(19) United States
(12) Patent Application Publication
(10) Pub. No.: US 2024/0251567 A1
(43) Pub. Date: Jul. 25, 2024

(54) SEMICONDUCTOR DEVICE

(71) Applicant: Semiconductor Energy Laboratory Co., Ltd., Atsugi-shi, Kanagawa-ken (JP)

(72) Inventors: Takanori MATSUZAKI, Atsugi (JP); Tatsuya ONUKI, Atsugi (JP); Yuki OKAMOTO, Ebina (JP)

(21) Appl. No.: 18/561,961

(22) PCT Filed: May 19, 2022
(86) PCT No.: PCT/IB2022/054652

§ 371 Date: Nov. 17, 2023

(30) Foreign Application Priority Data
May 28, 2021 (JP) 2021-090175
Jun. 4, 2021 (JP) 2021-094341

(51) Int. Cl. H10B 61/00; G11C 5/06; H10N 50/10; H10N 50/80

(52) U.S. Cl. CPC H10B 61/22; G11C 5/063; H10N 50/10; H10N 50/80

(57) ABSTRACT

A semiconductor device with a novel structure is provided. The semiconductor device includes a first substrate, a first element layer provided in contact with a second substrate, and a first through electrode provided in the second substrate and the first element layer. The first element layer includes a first memory cell, a first electrode, a second electrode, and a third electrode. The first memory cell includes a first transistor. The first transistor includes a semiconductor layer containing a metal oxide in a channel formation region. The first electrode is electrically connected to the third electrode via the second electrode. The third electrode is provided to be exposed on a surface of the first element layer. The first through electrode is provided to be exposed on a surface of the second substrate and is electrically connected to the first electrode. The second substrate and the first element layer are provided to be stacked in a direction perpendicular or substantially perpendicular to a surface of the first substrate. The first transistor is provided in a region overlapping with the first through electrode.

### TECHNICAL FIELD

In this specification, a semiconductor device and the like will be described.

In this specification, a semiconductor device refers to a device that utilizes semiconductor characteristics, and means a circuit including a semiconductor element (a transistor, a diode, a photodiode, or the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display device, a light-emitting device, a lighting device, an electronic device, and the like themselves may be semiconductor devices or may each include a semiconductor device.

### BACKGROUND ART

As a semiconductor applicable to a transistor, a metal oxide has been attracting attention. It has been reported that a transistor including a metal oxide semiconductor in a channel formation region (hereinafter referred to as an “oxide semiconductor transistor” or an “OS transistor” in some cases) has an extremely low off-state current (e.g., Non-Patent Documents 1 and 2). A variety of semiconductor devices using OS transistors have been manufactured (e.g., Non-Patent Documents 3 and 4).

The manufacturing process of an OS transistor can be incorporated in a CMOS process with a conventional transistor containing silicon in a channel formation region (a Si transistor), and an OS transistor can be stacked over a Si transistor. For example, Patent Document 1 discloses a structure in which a plurality of memory cell array layers including OS transistors are stacked over a substrate provided with Si transistors.

### REFERENCE

### Patent Document

[Patent Document 1] United States Patent Application Publication No. 2012/0063208

### Non-Patent Document

[Non-Patent Document 1] S. Yamazaki et al., “Properties of crystalline In—Ga—Zn-oxide semiconductor and its transistor characteristics,” Jpn. J. Appl. Phys., vol. 53, 04ED18 (2014).
[Non-Patent Document 2] K. Kato et al., “Evaluation of Off-State Current Characteristics of Transistor Using Oxide Semiconductor Material, Indium-Gallium-Zinc Oxide,” Jpn. J. Appl. Phys., vol. 51, 021201 (2012).
[Non-Patent Document 3] S. Amano et al., “Low Power LC Display Using In—Ga—Zn-Oxide TFTs Based on Variable Frame Frequency,” SID Symp. Dig. Papers, vol. 41, pp. 626-629 (2010).
[Non-Patent Document 4] T. Ishizu et al., “Embedded Oxide Semiconductor Memories: A Key Enabler for Low-Power ULSI,” ECS Tran., vol. 79, pp. 149-156 (2017).

### SUMMARY OF THE INVENTION

### Problems to be Solved by the Invention

OS transistors can be provided to be stacked and have an extremely low off-state current, and thus are suitable as access transistors in a memory cell and the like. In particular, a memory device, which is required to have improved memory density per unit area such as memory cell, preferably has a structure in which element layers each including a plurality of transistors are provided to be stacked.

In the case of the structure with stacked element layers, an increase in the number of stacked layers increases the number of steps necessary for manufacturing elements. Hence, in the case where element layers are stacked, a plurality of element layers provided on different substrates are preferably electrically connected via a through electrode such as a through silicon via (TSV) so as to be formed into one chip.

In the case where a plurality of element layers provided on different substrates are connected via a through electrode such as a TSV, however, elements such as transistors are difficult to be provided in regions where the through electrode is provided. In a semiconductor device including element layers connected via a through electrode such as a TSV, in particular, a significantly large diameter of an opening portion formed by the TSV relative to the element size might increase the area where transistors cannot be provided. This causes a problem in that the memory density per unit area cannot be increased in the semiconductor device including element layers connected via a through electrode such as a TSV.

An object of one embodiment of the present invention is to provide a semiconductor device or the like having a novel structure. Another object of one embodiment of the present invention is to provide a semiconductor device or the like functioning as a memory device that utilizes an extremely low off-state current and having a novel structure that allows a reduction of manufacturing cost. Another object of one embodiment of the present invention is to provide a semiconductor device or the like functioning as a memory device that utilizes an extremely low off-state current and having a novel structure that excels in low power consumption. Another object of one embodiment of the present invention is to provide a semiconductor device or the like functioning as a memory device that utilizes an extremely low off-state current and having a novel structure that allows a reduction in the size of the device. Another object of one embodiment of the present invention is to provide a semiconductor device or the like functioning as a memory device that utilizes an extremely low off-state current and having a novel structure that allows high reliability with small variations in electrical characteristics of transistors.

The description of a plurality of objects does not preclude the existence of each object. One embodiment of the present invention does not necessarily achieve all the objects described as examples. Furthermore, objects other than those listed are apparent from description of this specification, and such objects can be objects of one embodiment of the present invention.

### Means for Solving the Problems

One embodiment of the present invention is a semiconductor device including a first substrate, a first element layer provided in contact with a second substrate, and a first through electrode provided in the second substrate and the first element layer. The first element layer includes a first transistor, a first electrode, a second electrode, and a third electrode. The first transistor includes a semiconductor layer containing a metal oxide in a channel formation region. The first electrode is electrically connected to the third electrode via the second electrode. The third electrode is provided to be exposed on a surface of the first element layer. The first through electrode is provided to be exposed on a surface of the second substrate and is electrically connected to the first electrode. The second substrate and the first element layer are provided to be stacked in a direction perpendicular or substantially perpendicular to a surface of the first substrate. The first transistor is provided in a region overlapping with the first through electrode.

One embodiment of the present invention is a semiconductor device including a first substrate, a first element layer provided in contact with a second substrate, and a first through electrode provided in the second substrate and the first element layer. The first element layer includes a first memory cell, a first electrode, a second electrode, and a third electrode. The first memory cell includes a first transistor and a capacitor. The first transistor includes a semiconductor layer containing a metal oxide in a channel formation region. The first electrode is electrically connected to the third electrode via the second electrode. The third electrode is provided to be exposed on a surface of the first element layer. The first through electrode is provided to be exposed on a surface of the second substrate and is electrically connected to the first electrode. The second substrate and the first element layer are provided to be stacked in a direction perpendicular or substantially perpendicular to a surface of the first substrate. The first transistor and the capacitor are provided in a region overlapping with the first through electrode.

One embodiment of the present invention is a semiconductor device including a first substrate, a first element layer provided in contact with a second substrate, and a first through electrode provided in the second substrate and the first element layer. The first element layer includes a first memory cell, a first electrode, a second electrode, and a third electrode. The first memory cell includes a first transistor and a magnetic tunnel junction element. The first transistor includes a semiconductor layer containing a metal oxide in a channel formation region. The first electrode is electrically connected to the third electrode via the second electrode. The third electrode is provided to be exposed on a surface of the first element layer. The first through electrode is provided to be exposed on a surface of the second substrate and is electrically connected to the first electrode. The second substrate and the first element layer are provided to be stacked in a direction perpendicular or substantially perpendicular to a surface of the first substrate. The first transistor and the magnetic tunnel junction element are provided in a region overlapping with the first through electrode.

In the semiconductor device of one embodiment of the present invention, the magnetic tunnel junction element preferably has a stacked-layer structure of an unfixed layer, an insulating layer, and a fixed layer.

One embodiment of the present invention is a semiconductor device including a first substrate, a first element layer provided in contact with a second substrate, and a first through electrode provided in the second substrate and the first element layer. The first element layer includes a plurality of first memory cells, a first circuit, a first electrode, a second electrode, and a third electrode. The first memory cells and the first circuit each include a first transistor. The first transistor includes a semiconductor layer containing a metal oxide in a channel formation region. The first electrode is electrically connected to the third electrode via the second electrode. The third electrode is provided to be exposed on a surface of the first element layer. The first through electrode is provided to be exposed on a surface of the second substrate and is electrically connected to the first electrode. The second substrate and the first element layer are provided to be stacked in a direction perpendicular or substantially perpendicular to a surface of the first substrate. The first transistor is provided in a region overlapping with the first through electrode.

In the semiconductor device of one embodiment of the present invention, the plurality of first memory cells are preferably electrically connected to any one of a plurality of bit lines, and the first circuit preferably has a function of selecting any one of the plurality of bit lines and amplifying and outputting a potential of the selected bit line.

In the semiconductor device of one embodiment of the present invention, the first memory cell is preferably electrically connected to a word line, and the first circuit preferably has a function of amplifying a signal supplied to the word line.

In the semiconductor device of one embodiment of the present invention, the first substrate is preferably provided with a first peripheral circuit having a function of driving the first transistor.

In the semiconductor device of one embodiment of the present invention, the second electrode is preferably provided in a layer where an electrode connected to the first transistor is provided.

In the semiconductor device of one embodiment of the present invention, the second substrate is preferably a silicon substrate.

In the semiconductor device of one embodiment of the present invention, the metal oxide preferably contains In, Ga, and Zn.

Note that other embodiments of the present invention will be shown in the description of the following embodiments and the drawings.

### Effect of the Invention

With one embodiment of the present invention, a semiconductor device or the like having a novel structure can be provided. With one embodiment of the present invention, a semiconductor device or the like functioning as a memory device that utilizes an extremely low off-state current and having a novel structure that allows a reduction of manufacturing cost can be provided. With one embodiment of the present invention, a semiconductor device or the like functioning as a memory device that utilizes an extremely low off-state current and having a novel structure that excels in low power consumption can be provided. With one embodiment of the present invention, a semiconductor device or the like functioning as a memory device that utilizes an extremely low off-state current and having a novel structure that allows a reduction in the size of the device can be provided. With one embodiment of the present invention, a semiconductor device or the like functioning as a memory device that utilizes an extremely low off-state current and having a novel structure that allows high reliability with small variations in electrical characteristics of transistors can be provided.

The description of a plurality of effects does not preclude the existence of other effects. In addition, one embodiment of the present invention does not necessarily achieve all the effects described as examples. In one embodiment of the present invention, other objects, effects, and novel features are apparent from the description of this specification and the drawings.

### BRIEF DESCRIPTION OF THE DRAWINGS

FIG. 1A to FIG. 1C are diagrams illustrating a structure example of a semiconductor device.

FIG. 2A and FIG. 2B are diagrams illustrating a structure example of a semiconductor device.

FIG. 3A and FIG. 3B are diagrams illustrating a structure example of a semiconductor device.

FIG. 4A to FIG. 4C are diagrams each illustrating a structure example of a semiconductor device.

FIG. 5A to FIG. 5C are diagrams each illustrating a structure example of a semiconductor device.

FIG. 6A and FIG. 6B are diagrams illustrating a structure example of a semiconductor device.

FIG. 7 is a diagram illustrating a structure example of a semiconductor device.

FIG. 8 is a diagram illustrating a structure example of a semiconductor device.

FIG. 9 is a diagram illustrating a structure example of a semiconductor device.

FIG. 10A and FIG. 10B are diagrams illustrating a structure example of a semiconductor device.

FIG. 11A and FIG. 11B are diagrams illustrating a structure example of a semiconductor device.

FIG. 12A to FIG. 12C are diagrams illustrating a structure example of a semiconductor device.

FIG. 13 is a diagram illustrating a structure example of an imaging device.

FIG. 14 is a diagram illustrating a structure example of an imaging device.

FIG. 15A and FIG. 15B are diagrams illustrating a structure example of a semiconductor device.

FIG. 16A and FIG. 16B are diagrams illustrating a structure example of a semiconductor device.

FIG. 17A and FIG. 17B are diagrams illustrating a structure example of a semiconductor device.

FIG. 18A to FIG. 18C are diagrams illustrating a structure example of a semiconductor device.

FIG. 19A and FIG. 19B are diagrams each illustrating a structure example of a semiconductor device.

FIG. 20 is a block diagram illustrating a structure example of a semiconductor device.

FIG. 21 is a conceptual diagram illustrating a structure example of a semiconductor device.

FIG. 22A and FIG. 22B are schematic views illustrating examples of electronic components.

FIG. 23 is a diagram illustrating examples of electronic devices.

### MODE FOR CARRYING OUT THE INVENTION

Embodiments of the present invention will be described below. Note that one embodiment of the present invention is not limited to the following description, and it will be readily understood by those skilled in the art that modes and details of the present invention can be modified in various ways without departing from the spirit and scope of the present invention. One embodiment of the present invention therefore should not be construed as being limited to the following description of the embodiments.

Note that ordinal numbers such as “first”, “second”, and “third” in this specification and the like are used in order to avoid confusion among components. Thus, the ordinal numbers do not limit the number of components. In addition, the ordinal numbers do not limit the order of components. Furthermore, in this specification and the like, for example, a “first” component in one embodiment can be referred to as a “second” component in other embodiments or the scope of claims. Moreover, in this specification and the like, for example, a “first” component in one embodiment can be omitted in other embodiments or the scope of claims. Moreover, in this specification and the like, for example, a “first” component in one embodiment can be omitted in other embodiments or the scope of claims.

In some cases, the same components, components having similar functions, components made of the same material, components formed at the same time, and the like are denoted by the same reference numerals in the drawings and repeated description thereof is omitted.

In this specification, for example, a power supply potential VDD may be abbreviated to a potential VDD, VDD, or the like. The same applies to other components (e.g., a signal, a voltage, a circuit, an element, an electrode, and a wiring).

In the case where a plurality of components are denoted by the same reference numerals, and, particularly when they need to be distinguished from each other, an identification sign such as “_1”, “_2”, “[n]”, or “[m, n]” is sometimes added to the reference numerals. For example, a second wiring GL is referred to as a wiring GL[2].

### Embodiment 1

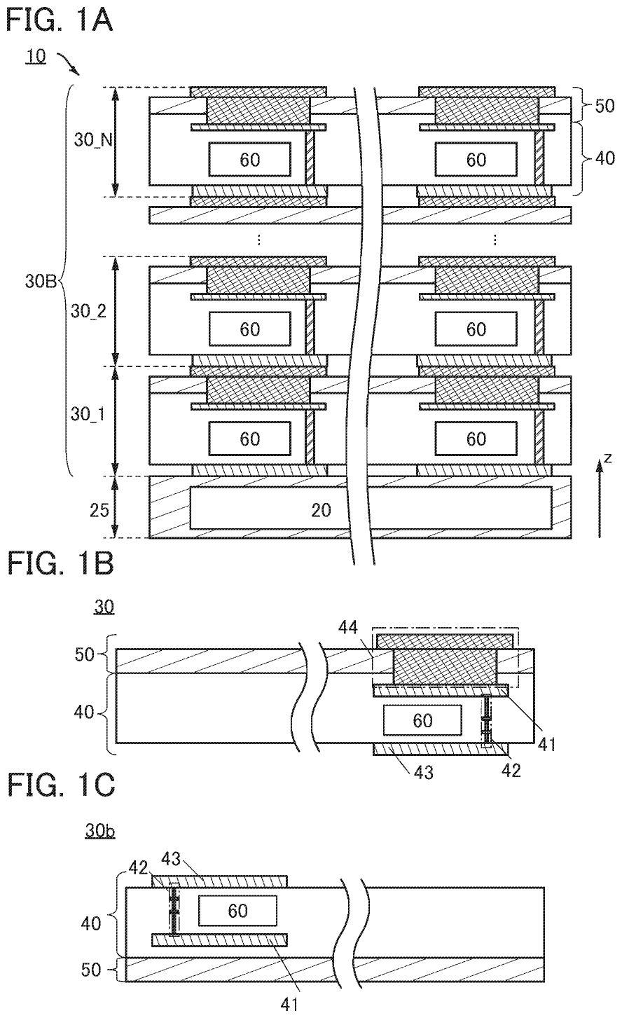

A structure example of a semiconductor device that is one embodiment of the present invention is described with reference to FIG. 1A to FIG. 1C. Note that a semiconductor device refers to a device that utilizes semiconductor characteristics, and means a circuit including a semiconductor element (a transistor, a diode, a photodiode, or the like) and a device including the circuit. For example, a semiconductor device that utilizes a transistor with an extremely low off-state current has a function of a memory device.

FIG. 1A to FIG. 1C are schematic cross-sectional views of the semiconductor device described in this embodiment. A semiconductor device 10 of one embodiment of the present invention includes a plurality of circuit units 30_1 to 30_N (Nis a natural number) over a substrate 25 as illustrated in FIG. 1A.

The circuit units 30_1 to 30_N (N is a natural number) are referred to as a circuit unit layer 30B in some cases. FIG. 1B and FIG. 1C are schematic cross-sectional views illustrating a circuit unit 30 that can be used as the circuit units 30_1 to 30_N.

The substrate 25 is provided with a peripheral circuit 20 for driving the circuit unit. Although the description is made assuming that the substrate 25 provided with the peripheral circuit 20 is a silicon substrate, this embodiment is not limited thereto. Note that the silicon substrate refers to a substrate including silicon as a semiconductor material, for example, a single crystal silicon substrate. Note that, without being limited to silicon, a material containing Ge (germanium), SiGe (silicon germanium), GaAs (gallium arsenide), GaAlAs (gallium aluminum arsenide), or the like may be used for the substrate. Note that in FIG. 1A, the peripheral circuit 20 provided in the substrate 25 is provided in a region overlapping with the circuit units 30_1 to 30_N; alternatively, the peripheral circuit 20 may be provided in the substrate 25 outside the region overlapping with the circuit units 30_1 to 30_N.

The circuit unit 30 includes a substrate 50 and an element layer 40 provided in contact with the substrate 50. The element layer 40 includes a memory circuit 60. The memory circuit 60 includes memory cells. The memory circuit 60 includes an element such as a transistor.

The circuit units 30_1 to 30_N are provided to be stacked in a direction perpendicular or substantially perpendicular to a surface of the substrate 25. In other words, the element layer 40 and the substrate 50 are provided to be stacked in a direction perpendicular or substantially perpendicular to the surface of the substrate 25. With this structure, the number of circuit units 30_1 to 30_N provided per unit area can be increased. Accordingly, the memory density of the memory cells included in the memory circuit 60 can be increased.

In the schematic cross-sectional view illustrated in FIG. 1A, the direction perpendicular or substantially perpendicular to the surface of the substrate 25 is defined as a z-axis direction in order to explain the position of components. Note that for easy understanding, the z-axis direction is sometimes referred to as a direction perpendicular to the surface of the substrate 25 in this specification. Note that “substantially perpendicular” refers to a state where an arrangement angle is greater than or equal to 85 degrees and less than or equal to 95 degrees.

The peripheral circuit 20 includes circuits for outputting signals for driving the circuit units 30_1 to 30_N, such as a row driver and a column driver. The peripheral circuit 20 may be referred to as a control circuit, a driver circuit, or a circuit.

The row driver is a circuit having a function of outputting signals for driving the memory cells to word lines. The word line has a function of transmitting a word signal to the memory cells. The row driver is sometimes referred to as a word line driver circuit. Note that the row driver includes a decoder circuit for selecting a word line in accordance with a designated address, a buffer circuit, and the like. The column driver is a circuit having a function of outputting signals for driving the memory cells to bit lines, a function of outputting data to be written to the memory cells, and a function of amplifying data read from the memory cells to the bit lines. A bit line has a function of transmitting data to the memory cells. The column driver is sometimes referred to as a bit line driver circuit. Note that the column driver includes a sense amplifier, a precharge circuit, a decoder circuit for selecting a bit line in accordance with a designated address, and the like.

The peripheral circuit 20 preferably drives the memory cells included in the memory circuit 60 at high speed. Thus, the peripheral circuit 20 preferably includes a transistor that operates at high speed. The transistor included in the peripheral circuit 20 is preferably a transistor that includes silicon in a channel formation region (a Si transistor) with high field-effect mobility.

FIG. 1B illustrates the circuit unit 30 that can be used as the circuit units 30_1 to 30_N. The circuit unit 30 includes the substrate 50 and the element layer 40 provided in contact with the substrate 50. The substrate 50 is a substrate where an element such as a transistor included in the element layer 40 is formed. As the substrate 50, a silicon substrate can be used.

The element layer 40 includes the memory circuit 60, an electrode 41, an electrode 42, and an electrode 43. The substrate 50 and the element layer 40 include a through electrode 44. The through electrode 44 is provided to be exposed on a surface of the substrate 50 and is electrically connected to the electrode 41. Note that the through electrode 44 is an electrode that is provided to penetrate the substrate 50 after the electrodes 41 to 43 are formed on the substrate 50.

The electrode 41 is electrically connected to the electrode 43 via the electrode 42. The electrode 43 is provided to be exposed on a surface of the element layer 40.

The electrodes 41 to 43 are electrodes that are provided on the element layer 40 side over the substrate 50 as in a circuit unit 30b illustrated in FIG. 1C.

The electrode 41 is an electrode that is formed over the substrate 50 with use of a conductor provided under a transistor and a capacitor included in the memory circuit 60. The electrode 41 is provided in a position where the through electrode 44 (not illustrated) is provided. Examples of materials that can be used for the electrode 41 include metals such as aluminum, titanium, chromium, nickel, copper, yttrium, zirconium, molybdenum, silver, tantalum, and tungsten, and an alloy containing any of these metals as its main component. A film containing any of these materials can be used in a single layer or as a stacked-layer structure. In particular, copper is suitable for the electrode 41.

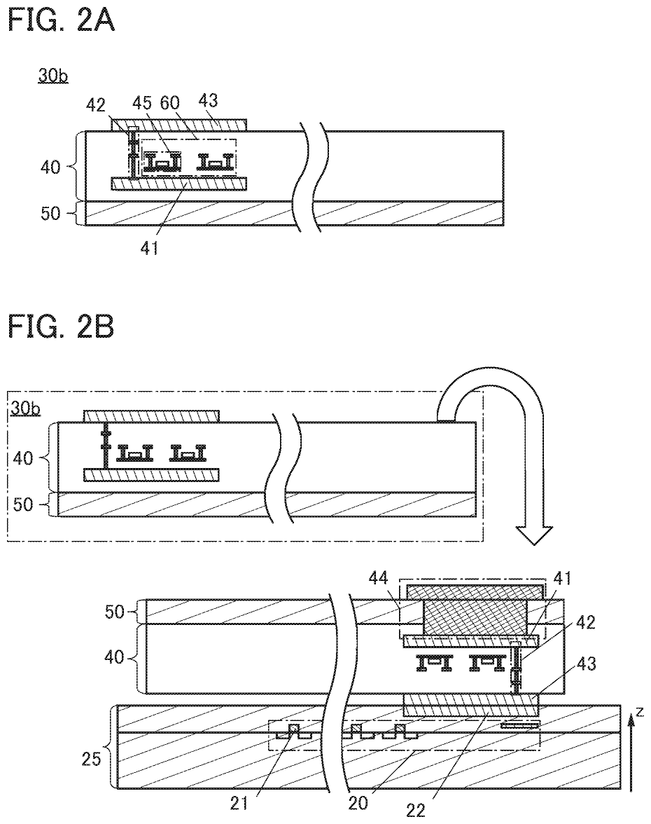

The electrode 42 is an electrode that is formed with use of a conductor provided in a layer where the transistor, the capacitor, and the like included in the memory circuit 60 are provided. The electrode 42 is an electrode that includes, for example as illustrated in FIG. 2A, a conductor provided in a layer where a conductor functioning as a gate electrode, a source electrode, or a drain electrode of a transistor 45 included in the memory circuit 60 is provided. Examples of materials that can be used for the electrode 42 include metals such as aluminum, titanium, chromium, nickel, copper, yttrium, zirconium, molybdenum, silver, tantalum, and tungsten, and an alloy containing any of these metals as its main component. A film containing any of these materials can be used in a single layer or as a stacked-layer structure.

The electrode 43 is an electrode that is provided in a position where the electrode 42 is provided to be exposed on the surface of the element layer 40 as in the circuit unit 30b illustrated in FIG. 1C. The electrode 43 can be formed using materials similar to those for the electrode 41.

A through electrode technique such as a TSV (Through Silicon Via) technique can be used for the through electrode 44. Specifically, the through electrode 44 can be formed after the circuit unit 30b is bonded to the substrate 25 in a face-down manner (face down bonding) as in a cross-sectional view illustrated in FIG. 2B. FIG. 2B illustrates, as the substrate to which the circuit unit 30b is bonded, the substrate 25 including a transistor 21 and an electrode 22 included in the peripheral circuit 20. In the case where the substrate 25 is a silicon substrate, the transistor 21 can be a Si transistor. The through electrode 44 is provided to penetrate the substrate 50 and to be connected to the electrode 43 provided in the element layer 40.

Note that the through electrode 44 can be provided in the following manner: a through hole reaching the electrode 41 in the element layer 40 is formed in the substrate 50; a base film such as a titanium nitride film is formed; then, a conductive layer such as a Cu layer is formed in the hole. Before the base film is formed, an insulating layer such as a silicon oxide layer may be provided on a side surface of the hole.

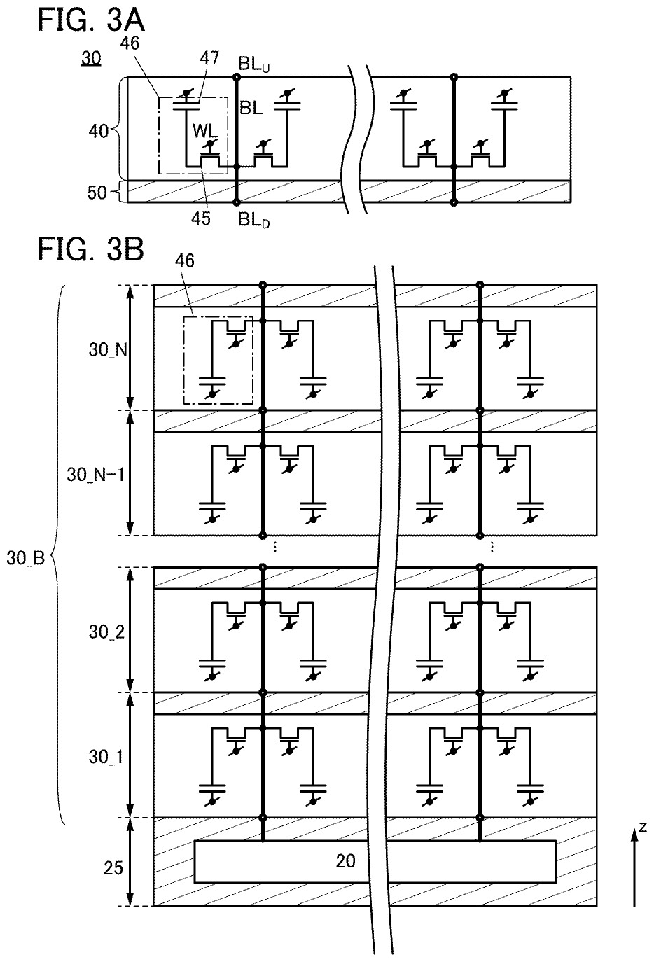

FIG. 3A illustrates a circuit configuration example of a memory cell included in the memory circuit 60. A memory cell 46 illustrated in FIG. 3A includes the transistor 45 and a capacitor 47. One of a source and a drain of the transistor 45 is connected to a wiring BL (denoted by a bold line). A gate of the transistor 45 is connected to a wiring WL. The other of the source and the drain of the transistor 45 is connected to the capacitor 47. Note that the wiring BL and the wiring WL may be referred to as a bit line and a word line, respectively.

In the wiring BL, the through electrode 44 provided to be exposed on the surface of the substrate 50 is provided as a terminal BL_{D} on the substrate 50 side. The electrode 43 provided to be exposed on the surface of the element layer 40 is provided as a terminal BL_{U} on the element layer 40 side. The terminal BL_{D} and the terminal BL_{U} can serve as terminals provided on the front and back of the circuit unit 30 when the through electrode 44 is electrically connected to the electrodes 41 to 43.

FIG. 3B illustrates a schematic view in which the plurality of circuit units 30_1 to 30_N each provided with the memory cells 46 are stacked over the substrate 25. As illustrated in FIG. 3B, wirings corresponding to the wirings BL (denoted by bold lines) are connected to the peripheral circuit 20 via the terminal BL_{D} and the terminal BL_{U} illustrated in FIG. 3A. Although not illustrated, the wiring WL can also be connected to the peripheral circuit 20.

The transistor 45 provided in the element layer 40 is preferably an OS transistor. The off-state current of an OS transistor is extremely low. Accordingly, electric charge corresponding to data written to the memory cell 46 can be retained in the capacitor 47 for a long time. In other words, data once written to the memory cell 46 can be retained for a long time. Therefore, the frequency of data refresh can be reduced, and the power consumption of the semiconductor device of one embodiment of the present invention can be reduced. Furthermore, OS transistors can be stacked and can be manufactured in the perpendicular direction by employing the same manufacturing process repeatedly, whereby an increase in memory density and a reduction in manufacturing cost can be achieved.

The memory cell 46 including the transistor 45 can be referred to as a DOSRAM (Dynamic Oxide Semiconductor Random Access Memory) using an OS transistor in a memory. The DOSRAM can be formed using one transistor and one capacitor, so that a high-density memory can be achieved. In addition, with the use of an OS transistor, a data retention period can be extended.

Although a transistor having a top-gate structure or a bottom-gate structure without a back gate electrode is illustrated as the transistor 45, the structure of the transistor 45 is not limited thereto. The transistor 45 preferably includes a back gate electrode. Controlling a potential applied to the back gate electrode can control the threshold voltage of the transistor 45. Thus, the on-state current of the transistor 45 can be increased and the off-state current of the transistor 45 can be decreased, for example.

The memory cell 46 using an OS transistor can be freely provided even in a region overlapping with the through electrode 44; thus, integration is facilitated. Accordingly, the number of memory cells arranged per unit area can be increased, and the memory density can be increased.

Furthermore, an OS transistor has electrical characteristics superior to those of a Si transistor in a high-temperature environment. Specifically, the ratio between an on-state current and an off-state current is large even at a high temperature higher than or equal to 125° C. and lower than or equal to 150° C.; thus, a favorable switching operation can be performed.

Note that the memory cell 46 may be a NOSRAM (Nonvolatile Oxide Semiconductor Random Access Memory). In the NOSRAM, data is rewritten by charge and discharge of the capacitor; therefore, there is theoretically no limit on rewrite cycles, and data can be written and read with low energy. In the case where data in the NOSRAM is multilevel data with three or more levels, data capacity per memory cell can be larger than that of a DOSRAM.

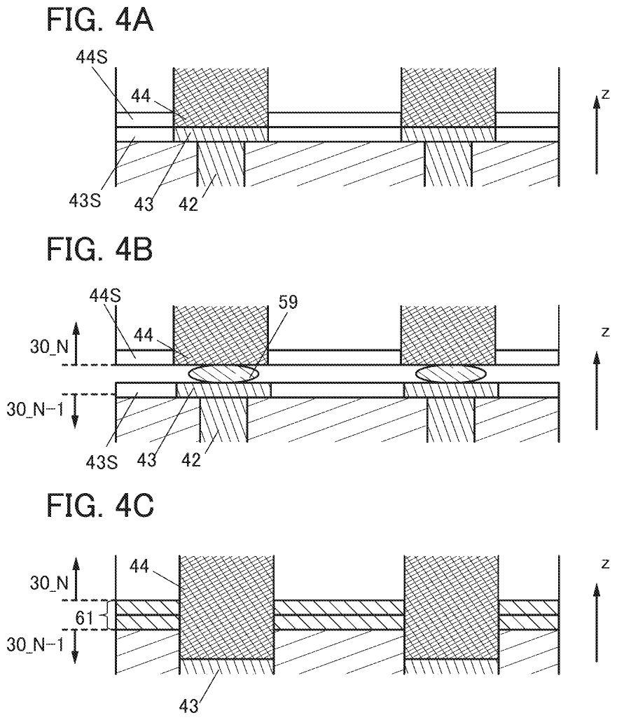

Note that in the structure described here, the circuit units 30 are connected to each other by directly connecting the through electrode 44 and the electrode 43. For example, it is possible to employ the structure illustrated in FIG. 4A, in which the through electrode 44 embedded in an insulating layer 44S and the electrode 43 embedded in an insulating layer 43S are connected by Cu—Cu bonding. The Cu—Cu bonding is a technique that establishes electrical continuity by connecting Cu (copper) pads. Alternatively, the through electrode 44 and the electrode 43 may be directly connected to each other without using Cu (copper) pads.

As illustrated in FIG. 4B, the through electrode 44 embedded in the insulating layer 44S and the electrode 43 embedded in the insulating layer 43S can be connected to each other via a metal bump 59 (also referred to as a micro-bump) provided between the circuit units (in the drawing, between the circuit unit 30_N and a circuit unit 30_N−1).

As illustrated in FIG. 4C, the through electrode 44 may be connected to the electrode 43 after the circuit units (the circuit unit 30_N and the circuit unit 30_N−1) are connected to each other with a bonding layer 61. Silicon oxide or the like is suitable for the bonding layer 61 because a planar surface can be formed and hydroxyl groups on the surface of the bonding layer 61 can be bonded to each other. Silicon oxide is preferred to silicon nitride or the like because of being capable of forming a more planar surface. In the case where the bonding layer 61 is formed using silicon oxide, hydroxyl groups on the surface of the silicon oxide of the bonding layer 61 are bonded to each other owing to the van der Waals force, and heat treatment performed later can generate a Silicon-Oxygen bond and a water molecule.

By the increased planarity of the bonding layer 61 or the like, bonding between the circuit units is possible in a range with an upper limit of 350° C. to 450° C. without exposure to high temperatures of 1000° C. or higher. That is, bonding between the circuit units is possible without exposure to high temperatures. Accordingly, variations in electrical characteristics of the OS transistor caused by exposing the circuit units to high temperatures can be inhibited. In addition, since the Si transistor is not exposed to high temperatures in bonding between the circuit units, using a copper wiring is possible.

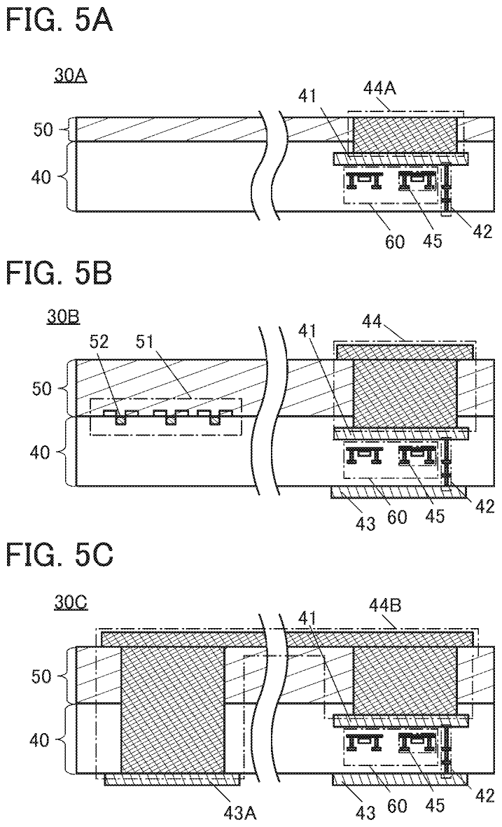

The circuit unit 30 may be configured to increase the planarity of a surface where the through electrode 44 is provided. For example, in a circuit unit 30A illustrated in FIG. 5A, a through electrode 44A has increased planarity on the surface of the substrate 50.

In the circuit unit 30, the substrate 50 may include a functional circuit 51 including a transistor 52 in a region where the through electrode 44 is not provided, as in a circuit unit 30B illustrated in FIG. 5B.

Note that the functional circuit 51 includes, for example, a circuit for outputting a signal for driving the memory circuit 60 included in the element layer 40. The functional circuit 51 preferably includes a transistor that operates at high speed. The transistor 52 included in the functional circuit 51 is preferably a Si transistor with high field-effect mobility. Alternatively, the functional circuit 51 may be a memory circuit, e.g., a DRAM (Dynamic Random Access Memory) including the transistor 52 provided on the substrate 50.

A DRAM including a Si transistor has higher data transfer speed than a DOSRAM including an OS transistor. On the other hand, the DOSRAM including an OS transistor has a lower data refresh frequency than the DRAM including a Si transistor and is effective in reducing power consumption. To achieve both high data transfer speed and low power consumption, a structure of switching the state where a DRAM or a DOSRAM is used in accordance with the data access state is effective.

Alternatively, the functional circuit 51 can be a sensor circuit provided in the substrate 50. For example, a photodiode can be provided when a silicon substrate is used as the substrate 50 and an impurity element is added thereto. The sensor circuit can be stacked over the circuit unit 30 including the memory circuit 60.

In the circuit unit 30, the through electrode 44 may be an electrode that penetrates the substrate 50 and the element layer 40. For example, a region where the functional circuit 51 is not provided may include a through electrode 44B that penetrates the substrate 50 and the element layer 40 as in a circuit unit 30C illustrated in FIG. 5C. The through electrode 44B can be connected to an electrode 43A provided in the layer where the electrode 43 is provided.

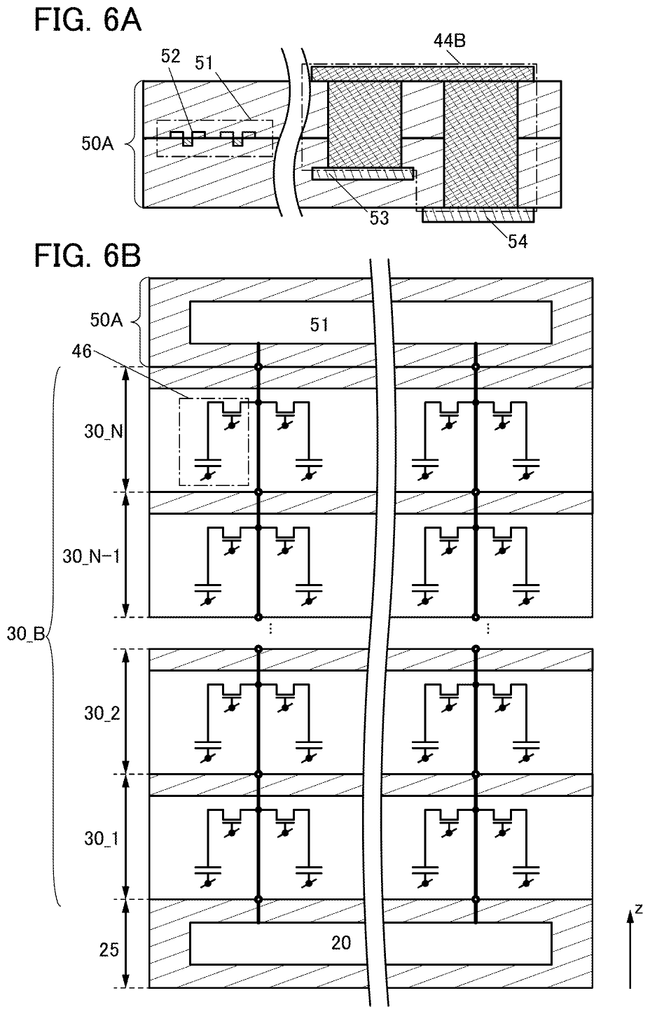

The element layer 40 may be omitted in the case where the substrate 50 is provided with the functional circuit 51 including the transistor 52 as illustrated in FIG. 5B and the functional circuit 51 is used as a memory circuit. In that case, as illustrated in FIG. 6A, the front and back surfaces of a substrate 50A may be electrically connected to each other via the through electrode 44B that penetrates the substrate 50A.

The substrate 50A including the functional circuit 51 can be provided over a circuit unit layer 30_B illustrated in FIG. 3B as illustrated in FIG. 6B. This achieves a semiconductor device in which the circuit unit 30 including the aforementioned memory cell 46 referred to as DOSRAM and the substrate 50A including a DRAM are stacked.

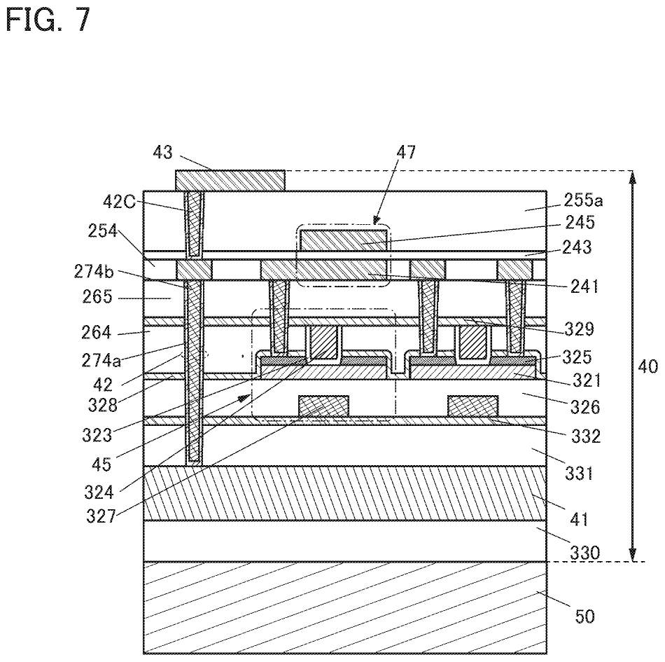

Next, a structure example of the element layer 40 is described with reference to FIG. 7, which illustrates an example.

The cross-sectional view in FIG. 7 illustrates the element layer 40 over the substrate 50. An insulating layer 330 and the electrode 41 are provided over the substrate 50. The transistor 45, the capacitor 47, the electrode 42, and the electrode 43 are illustrated over the electrode 41.

The transistor 45 is an OS transistor. The transistor 45 includes a semiconductor layer 321, an insulating layer 323, a conductive layer 324, a pair of conductive layers 325, an insulating layer 326, and a conductive layer 327.

An insulating layer 332 functions as a barrier layer that prevents diffusion of impurities such as water or hydrogen from an insulating layer 331 into the transistor 45 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 45, and part of the insulating layer 326 functions as a first gate insulating layer. An oxide insulating film such as a silicon oxide film is preferably used as at least part of the insulating layer 326 that is in contact with the semiconductor layer 321. A top surface of the insulating layer 326 is preferably planarized.

The semiconductor layer 321 is provided over the insulating layer 326. The semiconductor layer 321 preferably includes a metal oxide film having semiconductor characteristics (also referred to as an oxide semiconductor). As the metal oxide, for example, a metal oxide such as an In-M-Zn oxide (the element M is one kind or a plurality of kinds of aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like) may be used. Alternatively, as the oxide semiconductor, indium oxide, an In—Ga oxide, or an In—Zn oxide, that is, an oxide semiconductor containing In, Ga, and Zn may be used. Note that when an oxide semiconductor having a high proportion of indium is used, the on-state current, field-effect mobility, or the like of the transistor can be increased.

The pair of conductive layers 325 is provided on and in contact with the semiconductor layer 321 and functions as a source electrode and a drain electrode.

An insulating layer 328 is provided to cover top and side surfaces of the pair of conductive layers 325, side surfaces of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the above insulating layer 332 can be used.

An opening reaching the semiconductor layer 321 is provided in the insulating layer 328 and the insulating layer 264. The insulating layer 323 that is in contact with side surfaces of the insulating layer 264, the insulating layer 328, and the conductive layer 325 and a top surface of the semiconductor layer 321, and the conductive layer 324 are embedded in the opening. The conductive layer 324 functions as a second gate electrode, and the insulating layer 323 functions as a second gate insulating layer.

A top surface of the conductive layer 324, a top surface of the insulating layer 323, and a top surface of the insulating layer 264 are planarized so that their levels are the same or substantially the same, and an insulating layer 329 and an insulating layer 265 are provided to cover these layers.

The insulating layer 330, the insulating layer 331, the insulating layer 264, and the insulating layer 265 each function as an interlayer insulating layer. The insulating layer 329 functions as a barrier layer that prevents diffusion of impurities such as water or hydrogen from the insulating layer 265 or the like into the transistor 45. For the insulating layer 329, an insulating film similar to the above insulating layer 328 and the above insulating layer 332 can be used.

The electrode 42 electrically connected to one of the pair of conductive layers 325 or the electrode 41 is provided to be embedded in the insulating layer 328, the insulating layer 332, the insulating layer 331, the insulating layer 265, the insulating layer 329, and the insulating layer 264. Here, the electrode 42 preferably includes a conductive layer 274a, which covers a side surface and a bottom surface of the opening, and a conductive layer 274b, which is in contact with a top surface of the conductive layer 274a. At this time, a conductive material that does not easily allow diffusion of hydrogen and oxygen is preferably used for the conductive layer 274a.

The capacitor 47 is provided over the insulating layer 265.

The capacitor 47 includes a conductive layer 241, a conductive layer 245, and an insulating layer 243 between these conductive layers. The conductive layer 241 functions as one electrode of the capacitor 47, the conductive layer 245 functions as the other electrode of the capacitor 47, and the insulating layer 243 functions as a dielectric of the capacitor 47.

The conductive layer 241 is provided over the insulating layer 265 and is embedded in an insulating layer 254. The conductive layer 241 is electrically connected to one of a source and a drain of the transistor 45 via an electrode embedded in the insulating layer 265, the insulating layer 329, the insulating layer 264, and the insulating layer 328. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 47. An electrode 42C connected to the electrode 42 is provided in the insulating layer 255a, and the electrode 43 is provided over the electrode 42C. The electrode 42C can be provided in a manner similar to that of the electrode 42. The electrode 43 can be provided in a manner similar to that of the electrode 41. A variety of inorganic insulating films such as an oxide insulating film, a nitride insulating film, an oxynitride insulating film, and a nitride oxide insulating film can be suitably used as the insulating layer 255a.

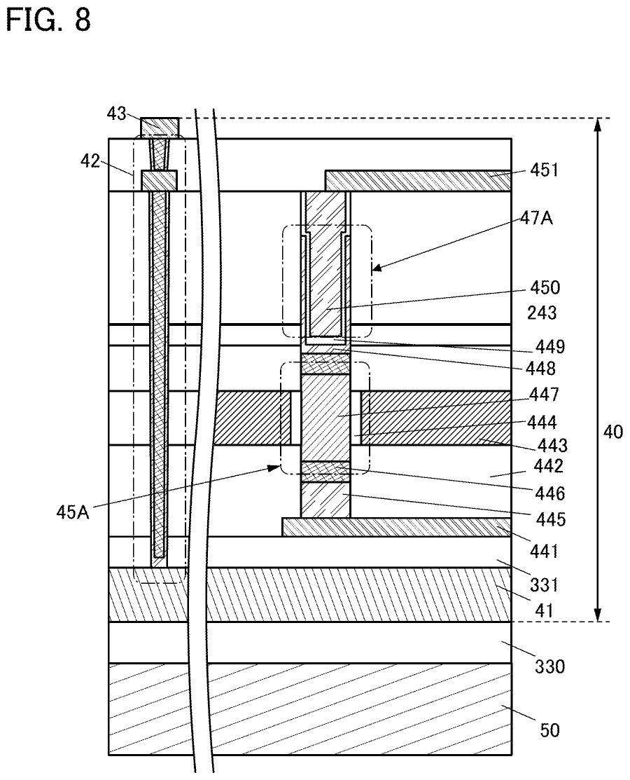

A schematic cross-sectional view of FIG. 8 illustrates a structure different from the structure of the transistor 45 illustrated in FIG. 7. FIG. 8 illustrates a vertical-channel transistor 45A, which is different from the transistor 45 in FIG. 7 in that the semiconductor layer is provided in a direction perpendicular to the substrate. A capacitor 47A illustrated in FIG. 8 has a (deep-hole) shape different from the planar shape of the capacitor 47 illustrated in FIG. 7.

The element layer 40 illustrated in FIG. 8, which includes the vertical-channel transistor 45A and the deep-hole capacitor 47A, includes the insulating layer 330, the electrode 41, and the insulating layer 331 over the substrate 50. A conductive layer 441 functioning as the wiring BL is provided over the insulating layer 331, and a hole portion is formed in a stacked body where an insulating layer 442 and a conductive layer 443 are stacked. An insulating layer 444 is formed on side surfaces of the conductive layer 443 including the hole portion. In the hole portion, a conductive layer 445, a conductive layer 446, a metal oxide layer 447, a conductive layer 448, an insulating layer 449, and a conductive layer 450 are provided. A conductive layer 451 is provided over the conductive layer 450.

Note that the metal oxide layers, the conductive layers, and the insulating layers can be formed using materials given above as the materials for the metal oxide layers, the conductive layers, and the insulating layers illustrated in FIG. 7. The metal oxide layers, the conductive layers, and the insulating layers can be formed by a sputtering method, a CVD method, a PLD method, an atomic layer deposition (ALD) method, or the like.

The conductive layer 443 functions as a gate of the transistor 45. The insulating layer 444 functions as a gate insulating film of the transistor 45A. The conductive layer 446 functions as a source electrode or a drain electrode of the transistor 45A. The metal oxide layer 447 functions as a semiconductor layer including a channel formation region of the transistor 45A. The conductive layer 448 and the conductive layer 450 function as electrodes of the capacitor 47A.

Note that a structure in which the front and back of the circuit unit are electrically connected to each other can be obtained by forming an opening reaching the electrode 41 in the hole portion where the transistor 45A and the capacitor 47A are provided and providing a conductor corresponding to the electrode 42 in the opening.

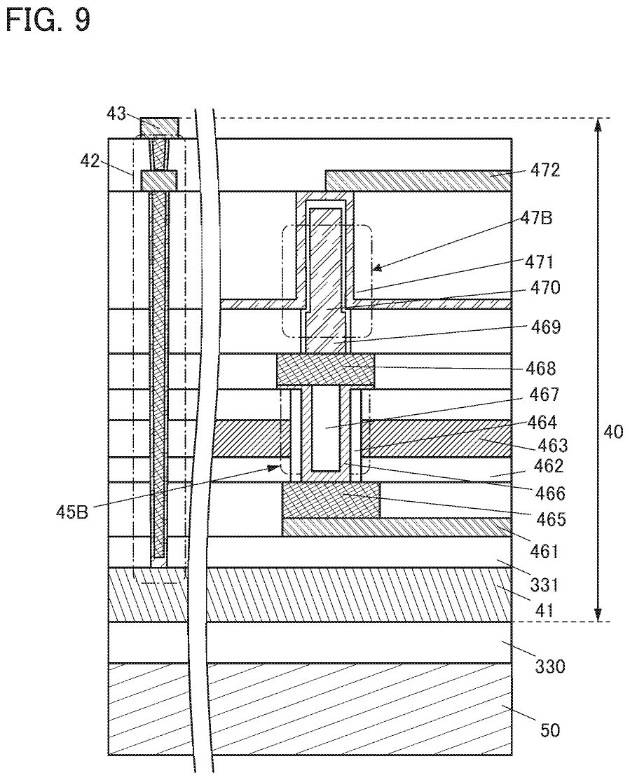

A schematic cross-sectional view of FIG. 9 illustrates a structure different from the structures of the transistors 45 and 45A illustrated in FIG. 7 and FIG. 8. FIG. 9 illustrates a vertical-channel transistor 45B including a semiconductor layer that is provided in a direction perpendicular to the substrate as in FIG. 8. The structure in FIG. 9 is different from that in FIG. 8 in that the semiconductor layer of the transistor 45B is provided along a wall surface of a hole portion. A capacitor 47B illustrated in FIG. 9 has a deep-hole shape with a structure different from the structure of the deep-hole capacitor illustrated in FIG. 8.

The element layer 40 illustrated in FIG. 9, which includes the vertical-channel transistor 45B and the deep-hole capacitor 47B, includes the insulating layer 330, the electrode 41, and the insulating layer 331 over the substrate 50. A conductive layer 461 functioning as the wiring BL is provided over the insulating layer 331, and a hole portion is formed in a stacked body where an insulating layer 462 and a conductive layer 463 are stacked. An insulating layer 464 is formed on side surfaces of the insulating layer 462 and the conductive layer 463 including the hole portion. In the hole portion, a metal oxide layer 466 in contact with a conductive layer 465 is provided and an insulating layer 467 is embedded therein. A conductive layer 468 in contact with the metal oxide layer is provided, and a conductive layer 469, an insulating layer 470, and a conductive layer 471 are provided thereover. A conductive layer 472 is provided over the conductive layer 471.

Note that the metal oxide layers, the conductive layers, and the insulating layers can be formed using materials given above as the materials for the metal oxide layers, the conductive layers, and the insulating layers illustrated in FIG. 7. The metal oxide layers, the conductive layers, and the insulating layers can be formed by a sputtering method, a CVD method, a PLD method, an atomic layer deposition (ALD) method, or the like.

The conductive layer 463 functions as a gate of the transistor 45B. The insulating layer 464 functions as a gate insulating film of the transistor 45B. The conductive layers 465 and 468 function as a source electrode or a drain electrode of the transistor 45B. The metal oxide layer 466 functions as a semiconductor layer including a channel formation region of the transistor 45B. The conductive layer 469 and the conductive layer 471 function as electrodes of the capacitor 47B.

Note that a structure in which the front and back of the circuit unit are electrically connected to each other can be obtained by forming an opening reaching the electrode 41 in the hole portion where the transistor 45B is provided and providing a conductor corresponding to the electrode 42 in the opening.

According to one embodiment of the present invention, in the case where a plurality of element layers provided on different substrates are connected via a through electrode, elements such as transistors can be provided in regions where the through electrode is provided. Hence, the memory density per unit area can be increased in the semiconductor device.

An OS transistor with an extremely low off-state current can be used as a transistor provided in an element layer. Accordingly, the frequency of refresh of data retained in memory cells can be reduced, and a semiconductor device with reduced power consumption can be obtained. OS transistors can be provided to be stacked and can be manufactured in the perpendicular direction by employing the same manufacturing process repeatedly, whereby manufacturing cost can be reduced. Furthermore, in one embodiment of the present invention, the memory density can be increased by arranging the transistors included in the memory cells in not a plane direction but the perpendicular direction, whereby the device can be downsized. Moreover, since an OS transistor has smaller variations in electrical characteristics than a Si transistor even in a high-temperature environment, the semiconductor device can function as a highly reliable memory device in which stacked and integrated transistors have small variations in electrical characteristics.

### Embodiment 2

In this embodiment, an example of the structure of a semiconductor device of one embodiment of the present invention, which is different from the structure in Embodiment 1, will be described. The above description can be referred to for portions similar to those in Embodiment 1, and detailed description of the portions is omitted.

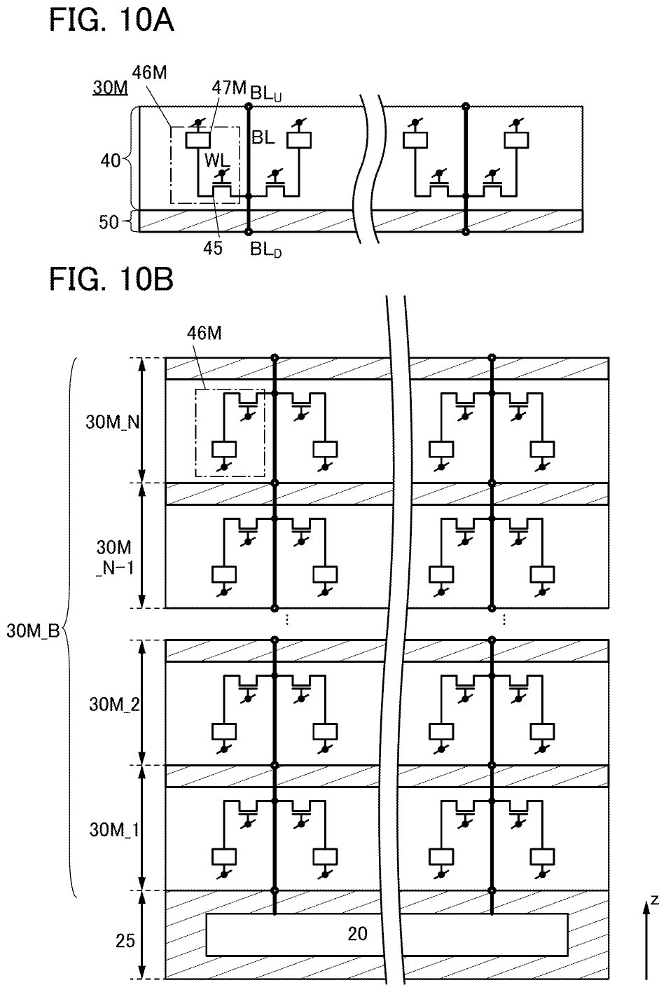

FIG. 10A is a schematic cross-sectional view of a semiconductor device described in this embodiment. A circuit unit 30M illustrated in FIG. 10A has a structure in which the element layer 40 of the circuit unit 30 described in Embodiment 1 includes a memory cell 46M including an STT-MRAM (Spin Transfer Torque-Magnetoresistive Random Access Memory), which is a memory using a magnetic tunnel junction (MTJ) element as a resistance-change memory element.

The memory cell 46M illustrated in FIG. 10A includes the transistor 45 as an OS transistor and an MTJ element 47M. In the wiring BL in FIG. 10A, the through electrode 44 provided to be exposed on the surface of the substrate 50 is provided as the terminal BL_{D} on the substrate 50 side. The electrode 43 provided to be exposed on the surface of the element layer 40 is provided as the terminal BL_{U} on the element layer 40 side. The terminal BL_{D} and the terminal BL_{U} can serve as terminals provided on the front and back of the circuit unit 30 as in FIG. 3A when the through electrode 44 is electrically connected to the electrodes 41 to 43.

FIG. 10B illustrates, as in FIG. 3B, a structure example of a circuit unit portion 30M_B including circuit units 30M_1 to 30M_N to each of which the circuit unit 30M illustrated in FIG. 10A can be applied. In FIG. 10B as well as in FIG. 10A, wirings corresponding to the wirings BL (denoted by bold lines) are connected to the peripheral circuit 20 via the terminal BL_{D} and the terminal BL_{U} illustrated in FIG. 10A. Although not illustrated, the wiring WL can also be connected to the peripheral circuit 20.

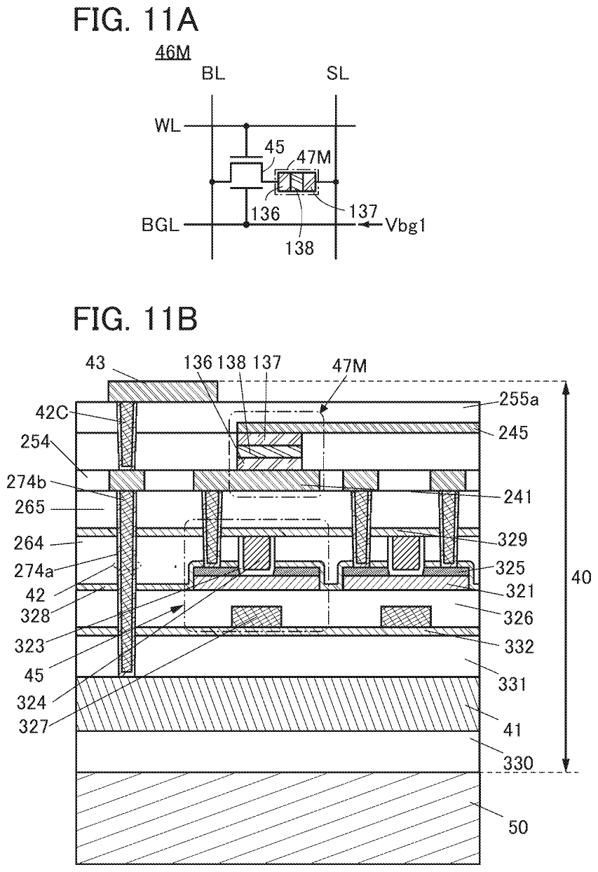

FIG. 11A illustrates a circuit diagram of the memory cell 46M including the MTJ element 47M. The memory cell 46M illustrated in FIG. 11A includes the transistor 45 and the MTJ element 47M. The transistor 45 is an OS transistor having a back gate. The MTJ element 47M includes an unfixed layer 136 (also referred to as a recording layer, a free layer, or a mobile layer) composed of a single layer or a stacked layer of ferromagnetic film, a fixed layer 137 (also referred to as a fixed magnetized layer, a pin layer, or a reference layer), and an insulating layer 138 (also referred to as a barrier layer, a tunnel insulating film, or a non-magnetic layer). Note that in this specification, the unfixed layer 136 and the fixed layer 137 of the MTJ element 47M are referred to as one terminal and another terminal, respectively.

One of the source and the drain of the transistor 45 is connected to the wiring BL (or BLB). The gate of the transistor 45 is connected to the wiring WL. The other of the source and the drain of the transistor 45 is connected to one terminal of the MTJ element 47M. The other terminal of the MTJ element 47M is connected to a wiring SL. The back gate of the transistor 45 is connected to the wiring BGL. The threshold voltage of the transistor 45 can be changed with a voltage Vbg.

FIG. 11B illustrates a structure in which the capacitor 47 is replaced by the MTJ element 47M in the schematic cross-sectional view of FIG. 7 described in Embodiment 1. The MTJ element 47M with the structure illustrated in FIG. 11B includes the unfixed layer 136, the fixed layer 137, and the insulating layer 138 between the conductive layer 241 and the conductive layer 245. Note that the MTJ element illustrated in FIG. 11B can be used in combination with the vertical-channel transistor 45A described in FIG. 8 or the vertical-channel transistor 45B described in FIG. 9.

For the insulating layer 138, magnesium oxide (MgO), aluminum oxide (Al₂O₃), or the like may be used. For the unfixed layer 136 and the fixed layer 137, a ferromagnetic material such as iron (Fe) or cobalt (Co), or an alloy thereof may be used. The unfixed layer 136, the fixed layer 137, and the insulating layer 138 can be formed with a single layer or a plurality of layers. Note that the unfixed layer 136, the fixed layer 137, and the insulating layer 138 may include an insulator or the like on their sidewall to facilitate processing.

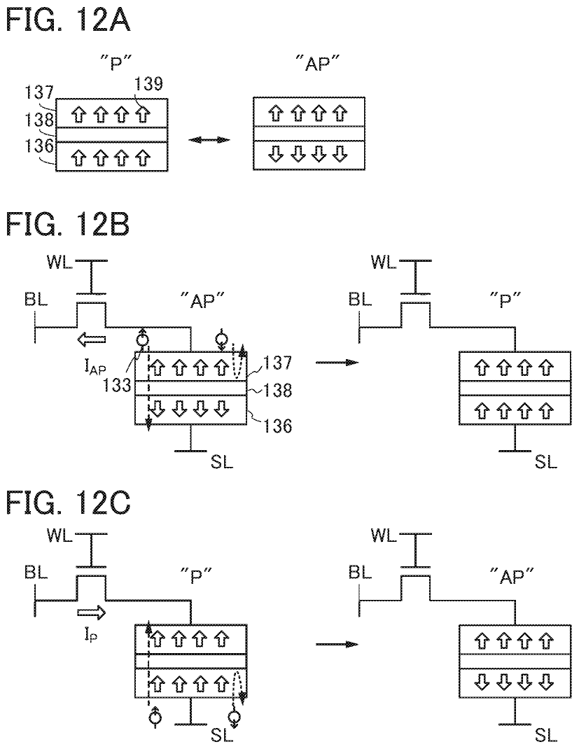

Here, the MTJ element 47M is described with reference to FIG. 12A to FIG. 12C.

FIG. 12A is a schematic view of a cross-sectional structure of the MTJ element 47M. The MTJ element 47M is formed of the unfixed layer 136 made of a ferromagnetic material and the fixed layer 137 made of a ferromagnetic material with the insulating layer 138 interposed therebetween.

The fixed layer 137 is a layer in which a magnetization direction, i.e., a spin direction is fixed. The unfixed layer 136 is a layer in which a magnetization direction, i.e., a spin direction is not fixed.

The resistance value of the MTJ element 47M changes depending on the relative direction of the magnetization direction of the unfixed layer 136 and the fixed layer 137 (indicated by arrow symbols 139 in FIG. 12A). That is, the MTJ element 47M can be of two states depending on the magnetization direction as illustrated in FIG. 12A. The resistance change, which depends on the magnetization direction, is referred to as tunnel magnetoresistance (hereinafter referred to as TMR). The state in which the unfixed layer 136 and the fixed layer 137 face the same magnetization direction is called a parallel state. The MTJ element 47M in this state has the minimum resistance value, and this state can be expressed as “P” or data “0”. The state in which the unfixed layer 136 and the fixed layer 137 face the opposite magnetization direction is called an antiparallel state. The MTJ element 47M in this state has the maximum resistance value, and this state can be expressed as “AP” or data “1”. By controlling the magnetization state of the unfixed layer 136 to be parallel or antiparallel to the fixed layer 137, the recording of “0” or “1”, that is, data writing can be performed. The MTJ element 47M is a resistance-change memory element utilizing the generation of resistance change in accordance with the direction of the magnetization direction.

The MTJ element 47M is nonvolatile and capable of high-speed rewriting, and has an unlimited number of rewrites in principle. The write current of the MTJ element 47M can be reduced together with the scaling down of the element.

Next, an operation principle of the MTJ element 47M will be described. FIG. 12B is a diagram illustrating a principle of writing using a spin injection method to change the magnetization direction of the unfixed layer 136 and the fixed layer 137 in the MTJ element 47M from the antiparallel state to the parallel state.

As illustrated in FIG. 12B, in order to write from the antiparallel state (“AP”) to the parallel state (“P”), a current I_{AP} flows in the direction from the unfixed layer 136 to the fixed layer 137. At this time, electrons flow in the opposite direction of the current I_{AP} (refer to the dotted arrow). Accordingly, injection of a spin 133 from the fixed layer 137 to the unfixed layer 136 occurs. The current which has been polarized by spinning operates on the magnetization of the unfixed layer 136, and the magnetization of the unfixed layer 136 reverses to the same direction as the fixed layer 137 to become the parallel state. The spin 133 to be injected is illustrated by a dashed arrow.

FIG. 12C is a diagram illustrating a principle of writing using a spin injection method to make the magnetization direction of the unfixed layer 136 and the fixed layer 137 from the parallel state to the antiparallel state in the MTJ element 47M.

As illustrated in FIG. 12C, in contrast to FIG. 12B, in order to write from the parallel state (“P”) to the antiparallel state (“AP”), a current I_{P} flows in the direction from the fixed layer 137 to the unfixed layer 136. The injected spin will be canceled out by the unfixed layer 136, but the electrons reflected by the insulating layer 138 will have magnetization in the opposite direction of the unfixed layer 136. The spin which has been reflected by the insulating layer 138 reverses the magnetization of the unfixed layer 136 to become the antiparallel state. Note that the reflected spin 133 is illustrated by a dotted arrow.

The magnetization direction of the unfixed layer 136 is reversed to be the opposite of the magnetization direction of the fixed layer 137 by the direction of the current flowing through the MTJ element 47M. When the magnetization directions are parallel to each other, the magnetic resistance decreases. Conversely, when the magnetization direction of the unfixed layer 136 is in the antiparallel state to the magnetization direction of the fixed layer 137, the magnetic resistance increases. Note that the unfixed layer 136 and the fixed layer 137 in the MTJ element 47M can be switched by switching the direction of current. In the MTJ element 47M, the current necessary for the reversal of magnetization can be reduced by scaling down the element.

An OS transistor can be provided in a position overlapping with a through electrode. Thus, a circuit including OS transistors can be provided in a position overlapping with the substrate 25 including Si transistors. An increase in the circuit area due to having both Si transistors and OS transistors can be inhibited. In order to inhibit an increase in the circuit area, a structure in which an MTJ element is provided over an OS transistor is also effective.

An OS transistor used as an access transistor needs to have a large W-width to supply a current for writing data to an MTJ element. In the case where a Si transistor is used as an access transistor, both scaling down and increasing the write current are needed. In the case of a structure in which an OS transistor is used as an access transistor, scaling down transistors and increasing the write current of the OS transistor can be separately designed by layer. Thus, within a limited cell area, enlarging the W-width of the OS transistor and scaling down the MTJ element can be realized all at one time. Accordingly, high integration and reducing power consumption can be both achieved. Furthermore, by making it possible to increase the amount of current required for rewriting the MTJ element, data can be written to and read from the MTJ element more reliably.

Furthermore, the OS transistor has a low off-state current. Thus, even in the case where a large W-width is designed to allow more current to flow through the access transistor, an increase in leakage current when the access transistor is in an off state can be inhibited. Accordingly, a memory device with lower power consumption can be achieved. Furthermore, in an OS transistor, by providing a potential to the back gate electrode, variation in electrical characteristics such as threshold voltage can be inhibited.

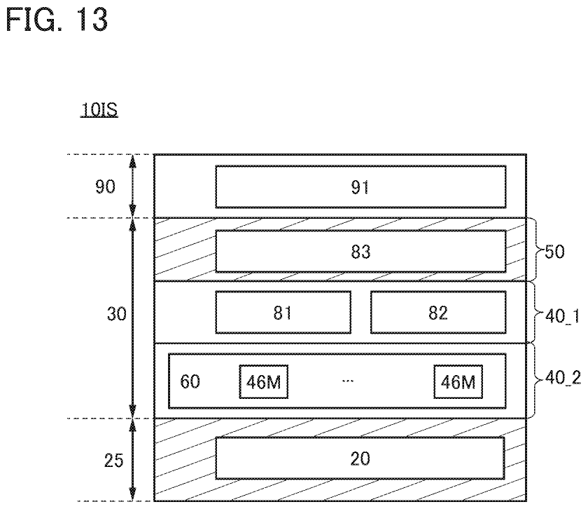

FIG. 13 is a block diagram illustrating an imaging device, which is an example of the semiconductor device including the memory cell 46M including the MTJ element 47M described in this embodiment.

An imaging device 10IS illustrated in FIG. 13 includes the circuit unit 30 and an optical conversion layer 90 over the substrate 25 including the peripheral circuit 20. The circuit unit 30 has a structure in which an element layer 40_1 and an element layer 40_2 are stacked on the substrate 50.

The substrate 50 includes a photoelectric conversion device 83. As the photoelectric conversion device 83, for example, a photodiode can be used. The photoelectric conversion device 83 preferably has sensitivity to visible light. For example, a Si photodiode that uses silicon in a photoelectric conversion layer can be used as the photoelectric conversion device 83.

In the element layer 40_1, for example, a pixel circuit 81 connected to an optical conversion device and a driver circuit 82 for the pixel circuit can be provided. The driver circuit 82 and the pixel circuit 81 can be formed through common steps. Note that the aforementioned photoelectric conversion device 83 can be regarded as a component of the pixel circuit 81. When each transistor included in the element layer 40_1 is an OS transistor, the transistors can be stacked over transistors included in the element layer 40_2.

In the element layer 40_2, the memory circuit 60 including a plurality of memory cells 46M can be provided. When each transistor included in the element layer 40_2 is an OS transistor, the transistors can be stacked over transistors included in the element layer 40_1.

In the case where a plurality of transistors are stacked, a polishing step and a bonding step are required to be performed a plurality of times. This causes issues such as a large number of manufacturing steps, the need for a dedicated apparatus, and a low yield; thus, the manufacturing cost is high. In one embodiment of the present invention, a circuit using OS transistors included in the element layers 40_1 and 40_2 is formed on the substrate 50 which is a Si device, whereby the number of polishing steps and the number of bonding steps can be reduced.

The memory circuit 60, the pixel circuit 81, and the photoelectric conversion device 83 are stacked; thus, global shutter operation, in which data of the photoelectric conversion device 83 are obtained in a plurality of pixel circuits 81 at once and are sequentially read out, can be realized with a simple circuit configuration.

In the peripheral circuit 20 included in the substrate 25, a plurality of transistors 21 as Si transistors are provided as described in Embodiment 1. The peripheral circuit 20 desirably processes data of the photoelectric conversion device 83 by high-speed operation. In such a structure, a transistor with high field-effect mobility is preferably used. For example, a Si transistor is preferably used. Examples of the Si transistor include a transistor including amorphous silicon and a transistor including crystalline silicon (microcrystalline silicon, low-temperature polysilicon, or single crystal silicon). Note that some or all transistors included in the driver circuit 82 of the pixel circuit may be Si transistors.

As the optical conversion layer 90, a color filter 91 can be used, for example. In addition, the optical conversion layer 90 can include a microlens array.

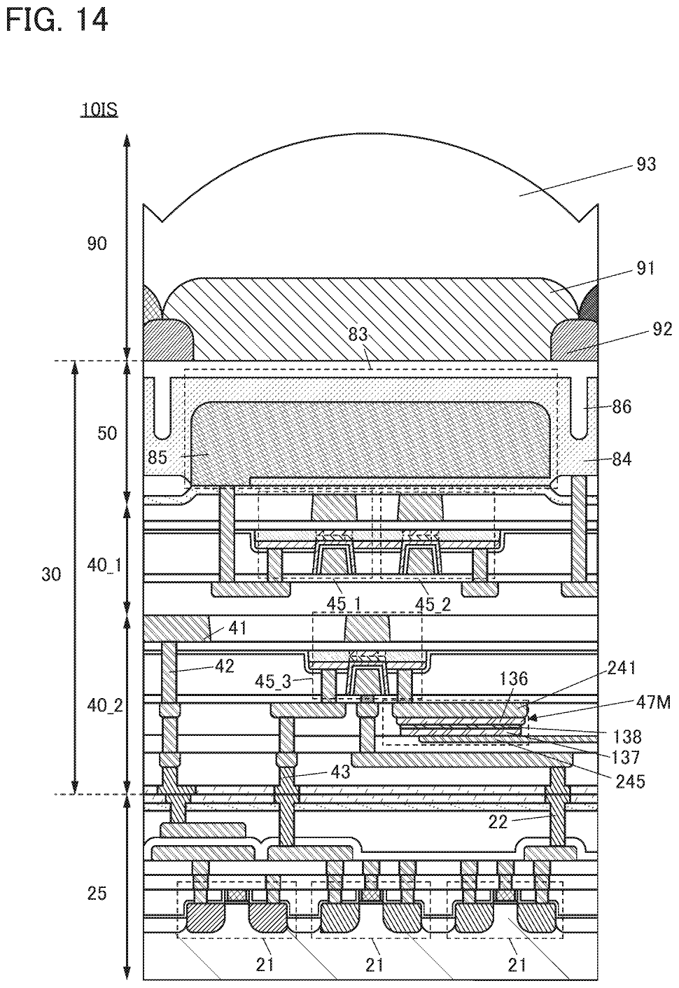

Next, FIG. 14 illustrates a schematic cross-sectional view including an element that can be used in the imaging device 10IS described in FIG. 13.

In the peripheral circuit 20 included in the substrate 25, a plurality of transistors 21 as Si transistors are provided as described in Embodiment 1. The substrate 25 includes the electrode 22 as described in Embodiment 1. The electrode 22 is an electrode for electrically connecting the plurality of transistors 21 and the circuit unit 30 in the upper layer.

The element layer 40_2 included in the circuit unit 30 includes the electrodes 41 to 43, a transistor 45_3, and the MTJ element 47M. The transistor 45_3 is a transistor corresponding to the transistor 45 and is an OS transistor. As described above, the MTJ element 47M includes, between the conductive layers 241 and 245, the unfixed layer 136 made of a ferromagnetic material and the fixed layer 137 made of a ferromagnetic material with the insulating layer 138 interposed therebetween.

The element layer 40_1 included in the circuit unit 30 includes transistors 45_1 and 45_2. The transistors 45_1 and 45_2 are OS transistors that can be used in the pixel circuit 81 and the driver circuit 82.

The substrate 50 included in the circuit unit 30 includes the photoelectric conversion device 83. The photoelectric conversion device 83 is a pn-junction photodiode formed in the substrate 50 as a silicon substrate and includes a p-type region 84 and an n-type region 85. The photoelectric conversion device 83 is a pinned photodiode, which can suppress dark current and reduce noise with the thin p-type region 84 provided on the surface side (current extraction side) of the n-type region 85.

The substrate 50 includes a groove 86 that separates pixels, and an insulating layer can be provided in the groove 86. This structure can inhibit carriers generated in the photoelectric conversion device 83 from leaking to an adjacent pixel. Note that an anti-reflection film may be provided on the top surface side of the substrate 50.

The optical conversion layer 90 includes the color filter 91, a light-blocking layer 92, and a microlens array 93.

The light-blocking layer 92 can inhibit entry of light into an adjacent pixel. As the light-blocking layer 92, a metal layer such as aluminum or tungsten can be used. The metal layer and a dielectric film functioning as an anti-reflection film may be stacked.

When the photoelectric conversion device 83 has sensitivity to visible light, the color filter 91 can be used as the optical conversion layer 90. When color filters of R (red), G (green), B (blue), Y (yellow), C (cyan), M (magenta), and the like are assigned to different pixels, a color image can be obtained.

Light passing through an individual lens of the microlens array 93 goes through the color filter 91 directly under the lens, and the photoelectric conversion device 83 is irradiated with the light. With the microlens array 93, collected light can be incident on the photoelectric conversion device 83; thus, photoelectric conversion can be efficiently performed. The microlens array 93 is preferably formed using a resin, glass, or the like having a high light-transmitting property with respect to light with an intended wavelength.

According to one embodiment of the present invention described in this embodiment, in the case where a plurality of element layers provided on different substrates are connected via a through electrode, elements such as transistors can be provided in regions where the through electrode is provided, as in Embodiment 1. Hence, the memory density per unit area can be increased in the semiconductor device.

An OS transistor with an extremely low off-state current can be used as a transistor provided in an element layer. Accordingly, the frequency of refresh of data retained in memory cells can be reduced, and a semiconductor device with reduced power consumption can be obtained. OS transistors can be provided to be stacked and can be manufactured in the perpendicular direction by employing the same manufacturing process repeatedly, whereby manufacturing cost can be reduced. Furthermore, in one embodiment of the present invention, the memory density can be increased by arranging the transistors included in the memory cells in not a plane direction but the perpendicular direction, whereby the device can be downsized. Moreover, since an OS transistor has smaller variations in electrical characteristics than a Si transistor even in a high-temperature environment, the semiconductor device can function as a highly reliable memory device in which stacked and integrated transistors have small variations in electrical characteristics.

### Embodiment 3

In this embodiment, an example of the structure of a semiconductor device of one embodiment of the present invention, which is different from the structures in Embodiment 1 and Embodiment 2, will be described. The above description can be referred to for portions similar to those in Embodiment 1 and Embodiment 2, and detailed description of the portions is omitted.

Described in this embodiment is an example of the structure in which the element layer 40 includes a memory circuit including a vertical-channel memory string.

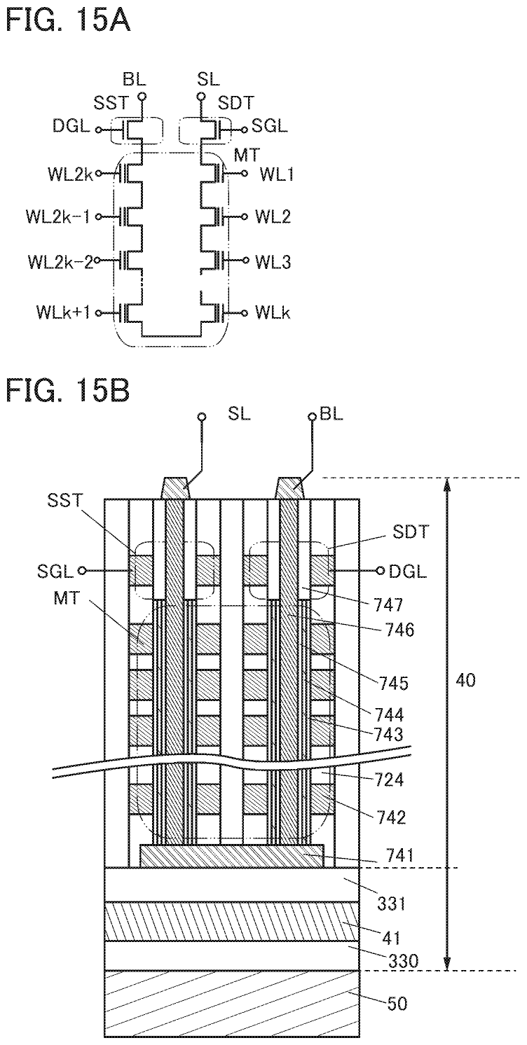

FIG. 15A illustrates a circuit configuration of a memory string. In the memory string illustrated in FIG. 15A, a selection transistor SST, memory transistors MT1 to MT2k (k is an integer greater than or equal to 1), and a selection transistor SDT are electrically connected in series between the wiring BL and the source line SL.

Note that the memory transistors MT1 to MT2k are transistors corresponding to word lines WL1 to WL2k. For example, the memory transistor connected to the word line WL1 is the memory transistor MT1. In the case where the memory transistors MT1 to MT2k are not distinguished from each other, these memory transistors are referred to as memory transistors MT. The same applies to the other elements.

The selection transistors SST and SDT, and the memory transistors MT1 to MT2k are each a vertical-channel transistor including a semiconductor layer formed of a metal oxide. The memory transistor MT includes a charge-accumulation layer and forms a nonvolatile memory cell.

Gates of the selection transistors SST and SDT are electrically connected to the selection gate line SGL and the selection gate line DGL, respectively. Gates of the memory transistors MT1 to MT2k are electrically connected to the word lines WL1 to WL2k, respectively.

FIG. 15B is a cross-sectional view illustrating an example of a memory string.

The element layer 40 including the memory string includes the insulating layer 330, the electrode 41, the insulating layer 331, and a conductive layer 741 over the substrate 50. A conductive layer 742 and an insulating layer 724 are alternately stacked to form a stacked body. A columnar structure body including an insulating layer 743, a charge-accumulation layer 744, an insulating layer 745, a metal oxide layer 746, and an insulating layer 747 is provided so as to fill a hole portion provided in the stacked body.

In the columnar structure body, a lower edge of the metal oxide layer 746 is electrically connected to the conductive layer 741, and an upper edge of the metal oxide layer 746 is electrically connected to one of the wiring BL and the wiring SL. The vicinity of a region where the conductive layer 742 overlaps with the insulating layer 743, the charge-accumulation layer 744, the insulating layer 745, and the metal oxide layer 746 functions as the memory transistor MT. The vicinity of a region where the conductive layer 742 overlaps with the insulating layer 747 and the metal oxide layer 746 functions as the selection transistors SDT and SST. The memory transistor MT or the selection transistors SDT and SST are electrically connected in series to form the memory string.

Note that the metal oxide layers, the conductive layers, and the insulating layers can be formed using materials given above as the materials for the metal oxide layers, the conductive layers, and the insulating layers illustrated in FIG. 7 in Embodiment 1. The metal oxide layers, the conductive layers, and the insulating layers can be formed by a sputtering method, a CVD method, a PLD method, an atomic layer deposition (ALD) method, or the like. For the charge-accumulation layer, for example, silicon nitride, silicon nitride oxide, aluminum oxide, hafnium oxide, or an oxide containing aluminum and hafnium can be used.

Although not illustrated, a structure in which the front and back of the circuit unit are electrically connected to each other can be obtained by forming an opening reaching the electrode 41 in the hole portion where the columnar structure body is provided and providing a conductor corresponding to the electrode 42 described in Embodiment 1.

According to one embodiment of the present invention described in this embodiment, in the case where a plurality of element layers provided on different substrates are connected via a through electrode, elements such as transistors can be provided in regions where the through electrode is provided, as in Embodiment 1. Hence, the memory density per unit area can be increased in the semiconductor device.

### Embodiment 4

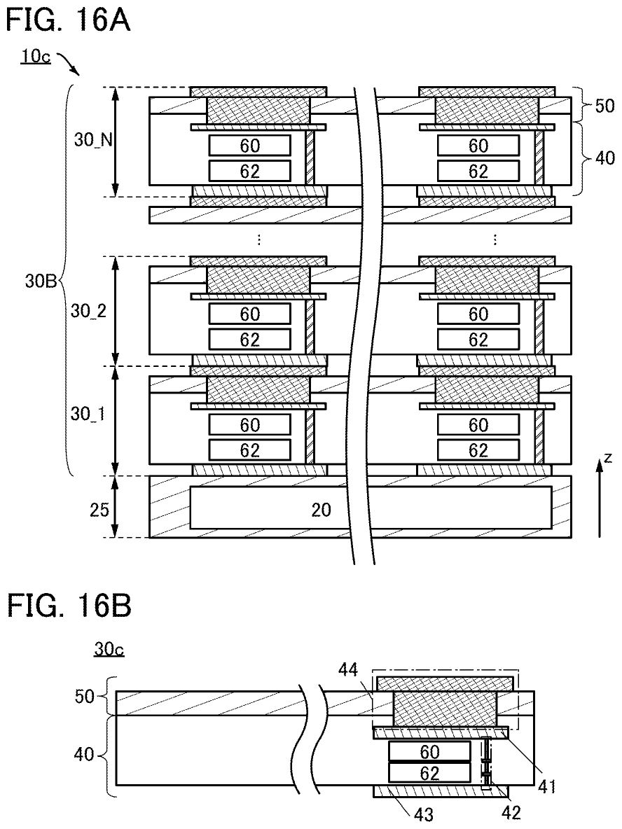

In this embodiment, a modification example of a circuit that can be used in the semiconductor device described above in Embodiment 1 will be described with reference to FIG. 16A to FIG. 18C.

FIG. 16A illustrates a structure example in which another functional circuit is added to the element layer 40 including the memory circuit 60 stacked on the substrate 50 in the structure described in FIG. 1A in Embodiment 1. The functional circuit has a function of, for example, selecting a wiring to which a data signal retained in the memory circuit 60 is output and amplifying the data signal.

FIG. 16A is a block diagram illustrating a semiconductor device 10c, in which the element layers 40 in the circuit unit 30_1 to the circuit unit 30_N described in Embodiment 1 include functional circuits 62 in addition to the memory circuits 60. The memory circuits 60 and the functional circuits 62 are provided to be stacked in the element layers 40 in the drawing; alternatively, the circuits may be provided in the same layer. For example, the memory circuits 60 and the functional circuits 62 may be formed using OS transistors provided in the same layer.

FIG. 16B illustrates a circuit unit 30c that can be used as the circuit units 30_1 to 30_N illustrated in FIG. 16A. The circuit unit 30c includes the substrate 50 and the element layer 40 provided in contact with the substrate 50.

The element layer 40 includes the functional circuit 62 in addition to the memory circuit 60, the electrode 41, the electrode 42, and the electrode 43. The substrate 50 and the element layer 40 include the through electrode 44. The functional circuit 62 is connected to the memory circuit 60 through a wiring provided in a layer where the electrode 42 is provided. The functional circuit 62 can be electrically connected to the peripheral circuit 20 and the element layer 40 included in another circuit unit 30c via the electrode 42, the electrode 41, the electrode 43, and the through electrode 44.

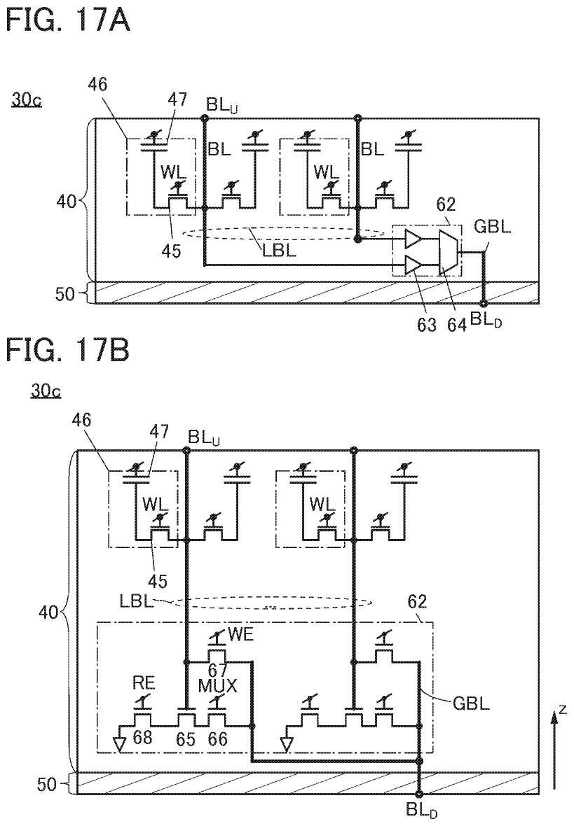

FIG. 17A illustrates an example of the functional circuit 62 connected to the memory cell 46 included in the memory circuit 60 illustrated in FIG. 3A. The functional circuit 62 includes amplifier circuits 63 connected to the respective wirings BL, and a selection circuit 64. The amplifier circuits 63 and the selection circuit 64 can each include an OS transistor and a capacitor as in the memory circuit 60 included in the element layer 40.

In FIG. 17A, a wiring connected to the memory cell 46 is denoted as a wiring LBL, and a wiring selected by the selection circuit 64 is denoted as a wiring GBL. The wiring GBL may be referred to as a global bit line. The wiring LBL may be referred to as a local bit line. The wiring LBL and the wiring GBL have functions of bit lines for data writing to or data reading from the memory cells. Note that in the drawings, the wiring LBL and the wiring GBL are sometimes denoted by bold lines, bold dotted lines, or the like to increase visibility.

The amplifier circuit 63 has a function of amplifying a current or a potential corresponding to the potential of the wiring LBL connecting a plurality of memory cells 46, and transmitting the current or the potential to the wiring GBL. The selection circuit 64 has a function of selecting a signal corresponding to the current or the potential output from the wiring LBL and transmitting the signal to the wiring GBL.

FIG. 17B illustrates a specific circuit configuration of the functional circuit 62 including the amplifier circuit 63 and the selection circuit 64 illustrated in FIG. 17A. In the functional circuit 62 illustrated in FIG. 17B, transistors 65 to 68 included in a circuit for achieving an amplification function and a selection function are illustrated. Each of the transistors 65 to 68 can be an OS transistor and is illustrated as an n-channel transistor.

The transistor 65 is a transistor for controlling the potential of the wiring GBL to a potential corresponding to the potential of the wiring LBL in a period during which data is read from the memory cell 46. The transistor 66 is a transistor functioning as a switch where a selection signal MUX is input to a gate and ON or OFF between a source and a drain is controlled in accordance with the selection signal MUX. The transistor 67 is a transistor functioning as a switch where a write control signal WE is input to a gate and ON or OFF between a source and a drain is controlled in accordance with the write control signal WE. The transistor 68 is a transistor functioning as a switch where a read control signal RE is input to a gate and ON or OFF between a source and a drain is controlled in accordance with the read control signal RE. Note that the ground potential GND, which is a fixed potential, is supplied to the source side of the transistor 68.

The transistor 65 can amplify the potential of the wiring LBL to be the potential of the wiring GBL. The transistor 66 can select a signal corresponding to the current or the potential output from the wiring LBL in accordance with the selection signal MUX and the control signal RE, and transmit the signal to the wiring GBL. The functional circuit 62 can write and read data to and from the memory cell 46 through the wiring GBL and the wiring LBL because of including the transistor 67 and the transistor 68.

The semiconductor device of one embodiment of the present invention can be manufactured by forming transistors in the perpendicular direction over the substrate by employing the same manufacturing process repeatedly. In one embodiment of the present invention, the memory density can be increased by arranging the OS transistors included in the memory cells in not a plane direction but the perpendicular direction, whereby the device can be downsized. In the case where the element layer 40 includes the functional circuit 62, the wiring LBL is connected to the gate of the transistor 65, whereby a data signal can be read to the wiring GBL by utilizing a slight potential difference of the wiring LBL.

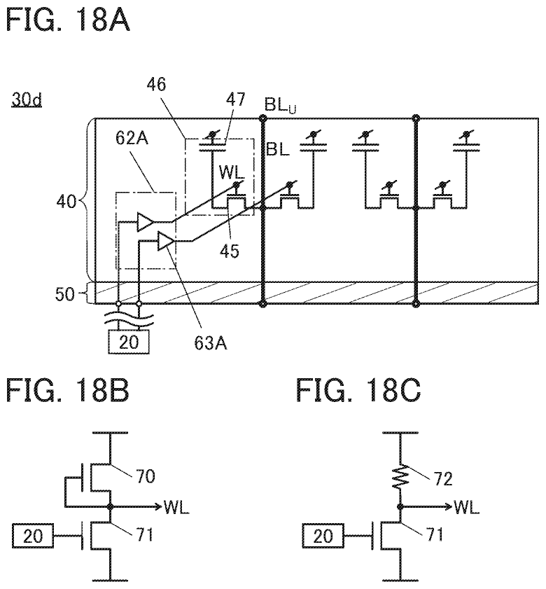

The functional circuit 62 described in one embodiment of the present invention may have another structure. For example, as in a functional circuit 62A included in a circuit unit 30d illustrated in FIG. 18A, an amplifier circuit 63A may be connected to the wiring WL of the memory cell 46.

The amplifier circuit 63A included in the functional circuit 62A has a function of amplifying and transmitting a control signal of the transistor 45 input to the wiring WL. This structure allows the transistor 45 to be surely turned on or off with use of a signal of the peripheral circuit 20 provided in the substrate 25.

In the case where the number of the circuit units 30_1 to 30_N is 100 or more, for example, the distance between the element layer 40 in the uppermost circuit unit and the peripheral circuit 20 can be short. In this case, the function of amplifying data in the functional circuits 62 provided in the respective circuit units enables data input and output between the uppermost memory cell and the peripheral circuit 20. Specifically, regardless of whether it is in the uppermost circuit unit or not, the data input and output between the memory cell 46 included in the element layer 40 and the peripheral circuit 20 is possible without a significant difference in data writing speed and data reading speed.

Note that the amplifier circuit 63A included in the functional circuit 62A can be provided in the element layer 40 when including an OS transistor. For example, the signal of the peripheral circuit 20 can be amplified and output to the wiring WL with use of an inverter circuit including a transistor 70 and a transistor 71 illustrated in FIG. 18B. Alternatively, the signal of the peripheral circuit 20 can be amplified and output to the wiring WL with use of an inverter circuit including a transistor 71 and a resistor 72 illustrated in FIG. 18C.

The structure described in this embodiment can be used in an appropriate combination with the structures described in the other embodiments and the like.

### Embodiment 5

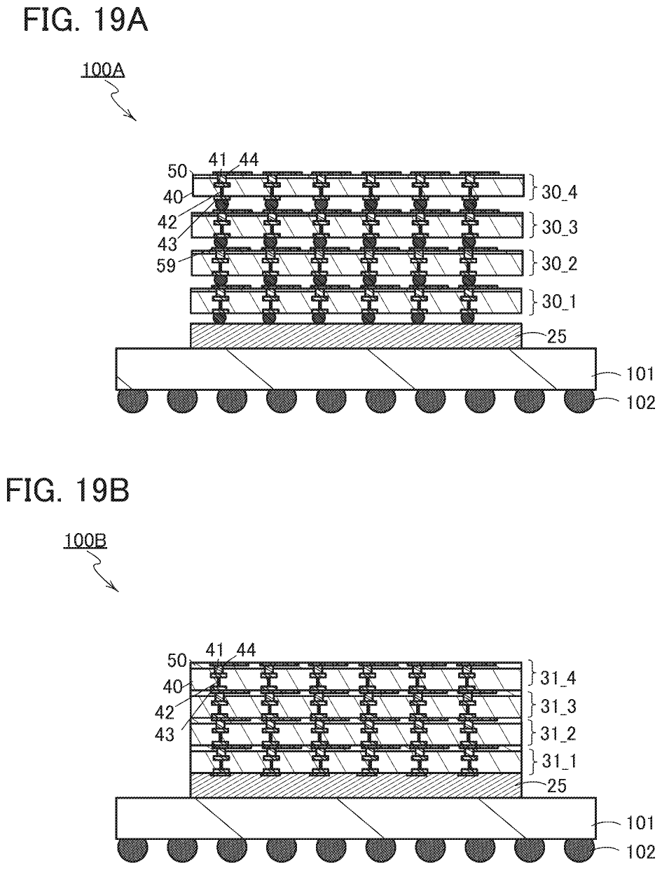

In this embodiment, an example of an integrated circuit (referred to as an IC chip) including the semiconductor device 10 is described. The semiconductor device 10 can be one IC chip by mounting a plurality of dies on a packaging substrate. FIG. 19A and FIG. 19B illustrate an example of the structure.

In a schematic cross-sectional view of an IC chip 100A illustrated in FIG. 19A, the substrate 25 is positioned over a package substrate 101 and, for example, four circuit units 30_1 to 30_4 are stacked over the substrate 25. Solder balls 102 for connecting the IC chip 100A to a printed circuit board or the like are provided on the packaging substrate 101. The circuit units 30_1 to 30_4 can be stacked by repeating the structure in which an OS transistor is formed in the element layer 40 in contact with the substrate 50. Furthermore, the peripheral circuit (not illustrated) provided in the substrate 25 and each circuit included in the circuit units 30_1 to 30_4 can be connected by the through electrode 44 provided to penetrate the substrate 50 and the element layer 40 in each layer and the electrodes 41 to 43 provided in the element layer. In addition, the layers can be electrically connected to each other via the through electrode 44 provided to penetrate each layer and the metal bump 59 (also referred to as the micro-bump) provided between the layers of the electrode 43.

For another example, in a schematic cross-sectional view of an IC chip 100B illustrated in FIG. 19B, the substrate 25 is positioned over the package substrate 101 and, for example, the four circuit units 30_1 to 30_4 are stacked over the substrate 25. The peripheral circuit (not illustrated) provided in the substrate 25 and the memory circuits (not illustrated) included in the circuit units 30_1 to 30_4 are bonded to each other using the electrode 43 and the through electrode 44 among the through electrode 44 provided to penetrate the substrate 50 and the element layer 40 in each layer and the electrodes 41 to 43 provided in the element layer. As a technique for electrically bonding different layers using the electrode 43 and the through electrode 44, Cu—Cu bonding can be used. Cu—Cu bonding is a technique that establishes electrical continuity by connecting Cu (copper) pads.

### Embodiment 6

In this embodiment, details of the peripheral circuit 20 including circuits for driving the memory circuit 60 functioning as the memory device in the semiconductor device 10 described in Embodiment 1 will be described.

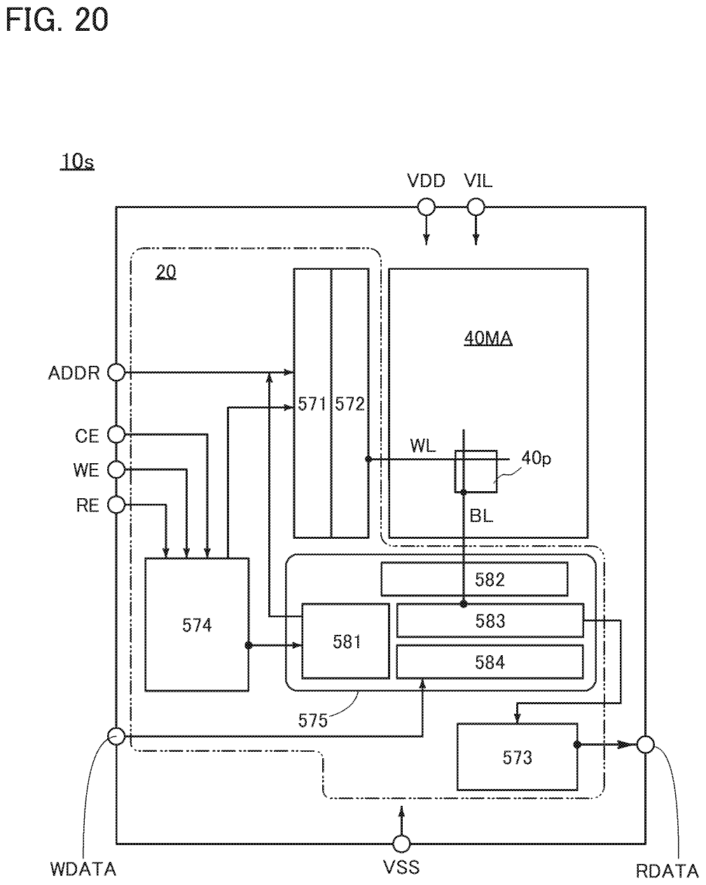

FIG. 20 is a block diagram illustrating a structure example of a semiconductor device functioning as a memory device. A semiconductor device 10s includes the peripheral circuit 20 and a memory cell array 40MA including a plurality of memory circuits 40p. The peripheral circuit 20 includes a row decoder 571, a word line driver circuit 572, a column driver 575, an output circuit 573, and a control logic circuit 574.

The column driver 575 includes a column decoder 581, a precharge circuit 582, an amplifier circuit 583, and a write circuit 584. The precharge circuit 582 has a function of precharging the wiring BL and the like. The amplifier circuit 583 has a function of amplifying a data signal read from the wiring BL. The amplified data signal is output to the outside of the semiconductor device 10s as a digital data signal RDATA through the output circuit 573.

As power supply voltage from the outside, low power supply voltage (VSS), high power supply voltage (VDD) for the peripheral circuit 20, and high power supply voltage (VIL) for the memory cell array 40MA are supplied to the semiconductor device 10s.

Control signals (CE, WE, and RE), an address signal ADDR, and a data signal WDATA are also input to the semiconductor device 10s from the outside. The address signal ADDR is input to the row decoder 571 and the column decoder 581, and WDATA is input to the write circuit 584.

The control logic circuit 574 processes the signals (CE, WE, and RE) input from the outside, and generates control signals for the row decoder 571 and the column decoder 581. CE is a chip enable signal, WE is a write enable signal, and RE is a read enable signal. The signals processed by the control logic circuit 574 are not limited thereto, and other control signals may be input as necessary. For example, a control signal for determining a defective bit may be input so that a defective bit may be identified with a data signal read from an address of a particular memory cell.

Note that whether each circuit or each signal described above is provided or not can be appropriately determined as needed.

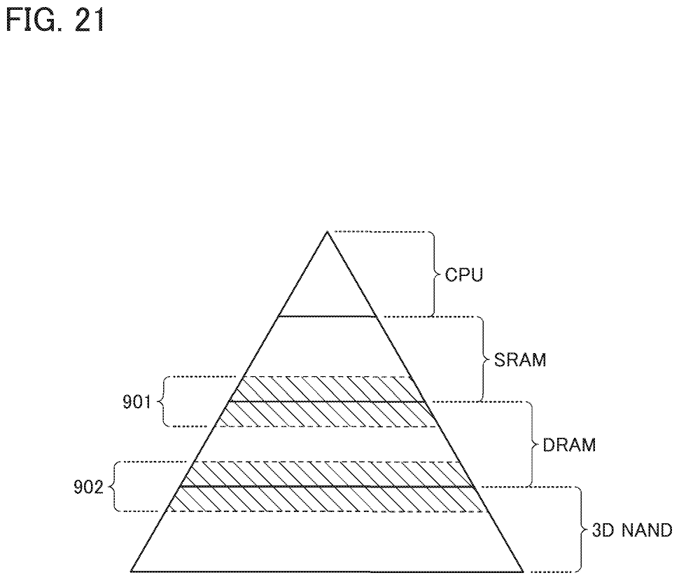

In general, a variety of memory devices (memories) are used in semiconductor devices such as a computer in accordance with the intended use. FIG. 21 shows a hierarchy diagram showing a variety of memory devices with different levels. The memory devices at the upper levels of the diagram require higher access speed, and the memory devices at the lower levels require larger memory capacity and higher memory density. FIG. 21 illustrates, sequentially from the top level, a memory included as a register in an arithmetic processing unit such as a CPU, an SRAM (Static Random Access Memory), a DRAM (Dynamic Random Access Memory), and a 3D NAND memory.

A memory included as a register in an arithmetic processing unit such as a CPU is used for temporary storage of arithmetic operation results, for example, and thus is frequently accessed by the arithmetic processing unit. Accordingly, high operation speed is required rather than memory capacity. In addition, the register also has a function of retaining settings information of the arithmetic processing unit, for example.

An SRAM is used for a cache, for example. The cache has a function of retaining a copy of part of data retained in a main memory. By copying data that is frequently used and retaining the copy of the data in the cache, access speed to the data can be increased.

A DRAM is used for the main memory, for example. The main memory has a function of retaining a program, data, or the like read from a storage. The memory density of a DRAM is approximately 0.1 to 0.3 Gbit/mm².

A 3D NAND memory is used for a storage, for example. A storage has a function of retaining data that needs to be retained for a long time or a variety of programs used in an arithmetic processing unit, for example. Therefore, a storage needs to have high memory capacity and high memory density rather than operating speed. The memory density of a memory device used for a storage is approximately 0.6 to 6.0 Gbit/mm².

The semiconductor device functioning as the memory device of one embodiment of the present invention operates fast and can retain data for a long time. The semiconductor device of one embodiment of the present invention can be suitably used as a semiconductor device positioned in a boundary region 901 including both the level in which a cache is positioned and the level in which a main memory is positioned. Furthermore, the semiconductor device of one embodiment of the present invention can be suitably used as a semiconductor device positioned in a boundary region 902 including both the level in which a main memory is positioned and the level in which a storage is positioned.

### Embodiment 7

In this embodiment, examples of electronic components and electronic devices in which the semiconductor device or the like described in the above embodiment is incorporated will be described.

### <Electronic Component>

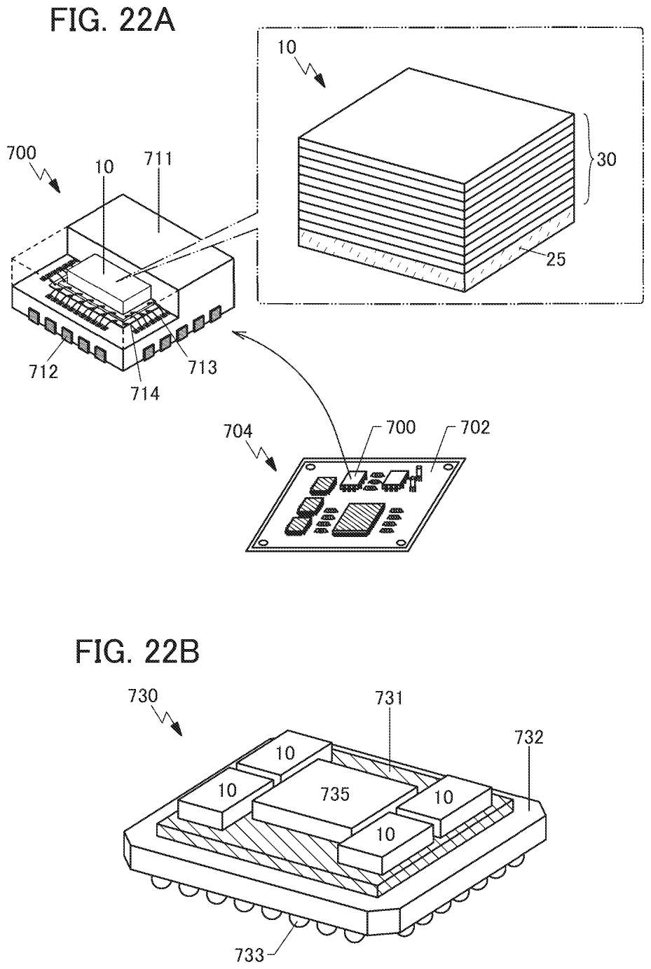

First, examples of electronic components in which the semiconductor device 10 or the like is incorporated are described with reference to FIG. 22A and FIG. 22B.

FIG. 22A illustrates a perspective view of an electronic component 700 and a substrate (a mounting board 704) on which the electronic component 700 is mounted. The electronic component 700 illustrated in FIG. 22A includes the semiconductor device 10 in which the circuit units 30 are stacked over the substrate 25 in a mold 711. The semiconductor device 10 described in Embodiment 1 can be used as the semiconductor device 10. Part of the electronic component is not reflected on FIG. 22A so that FIG. 22A illustrates the inside of the electronic component 700. The electronic component 700 includes a land 712 outside the mold 711. The land 712 is electrically connected to an electrode pad 713, and the electrode pad 713 is electrically connected to the semiconductor device 10 via a wire 714. The electronic component 700 is mounted on a printed circuit board 702, for example. A plurality of such electronic components are combined and electrically connected to each other on the printed circuit board 702, so that the mounting board 704 is completed.

FIG. 22B illustrates a perspective view of an electronic component 730. The electronic component 730 is an example of a SiP (System in package) or an MCM (Multi Chip Module). In the electronic component 730, an interposer 731 is provided on a packaging substrate 732 (a printed circuit board), and a semiconductor device 735 and a plurality of semiconductor devices 10 are provided on the interposer 731.

The electronic component 730 using the semiconductor devices 10 as high bandwidth memory (HBM) is illustrated as an example. In addition, an integrated circuit (semiconductor device) such as a CPU, a GPU, or an FPGA can be used for the semiconductor device 735.

As the packaging substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the packaging substrate 732. Accordingly, the interposer is sometimes referred to as a “redistribution substrate” or an “intermediate substrate”. Furthermore, a through electrode is provided in the interposer 731 and the through electrode is used to electrically connect an integrated circuit and the packaging substrate 732 in some cases. Moreover, for a silicon interposer, a TSV (Through Silicon Via) can also be used as the through electrode.

A silicon interposer is preferably used as the interposer 731. A silicon interposer can be manufactured at lower cost than an integrated circuit because it is not necessary to provide an active element. Meanwhile, since wirings of a silicon interposer can be formed through a semiconductor process, formation of minute wirings, which is difficult for a resin interposer, is easy.

In order to achieve a wide memory bandwidth, many wirings need to be connected to HBM. Therefore, formation of minute and high-density wirings is required for an interposer on which HBM is mounted. For this reason, a silicon interposer is preferably used as the interposer on which HBM is mounted.

In addition, in a SiP, an MCM, or the like using a silicon interposer, a decrease in reliability due to a difference in expansion coefficient between an integrated circuit and the interposer is less likely to occur. Furthermore, a silicon interposer has high surface flatness, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on an interposer.

In addition, a heat sink (a radiator plate) may be provided to overlap with the electronic component 730. In the case where a heat sink is provided, the heights of integrated circuits provided on the interposer 731 are preferably aligned with each other. For example, in the electronic component 730 described in this embodiment, the heights of the semiconductor device 10 and the semiconductor device 735 are preferably aligned with each other.

To mount the electronic component 730 on another substrate, an electrode 733 may be provided on the bottom portion of the packaging substrate 732. FIG. 22B illustrates an example in which the electrode 733 is formed of a solder ball. When solder balls are provided in a matrix on the bottom portion of the packaging substrate 732, BGA (Ball Grid Array) mounting can be achieved. Alternatively, the electrode 733 may be formed of a conductive pin. When conductive pins are provided in a matrix on the bottom portion of the packaging substrate 732, PGA (Pin Grid Array) mounting can be achieved.

The electronic component 730 can be mounted on another substrate by various mounting methods, not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be used.

### <Electronic Device>

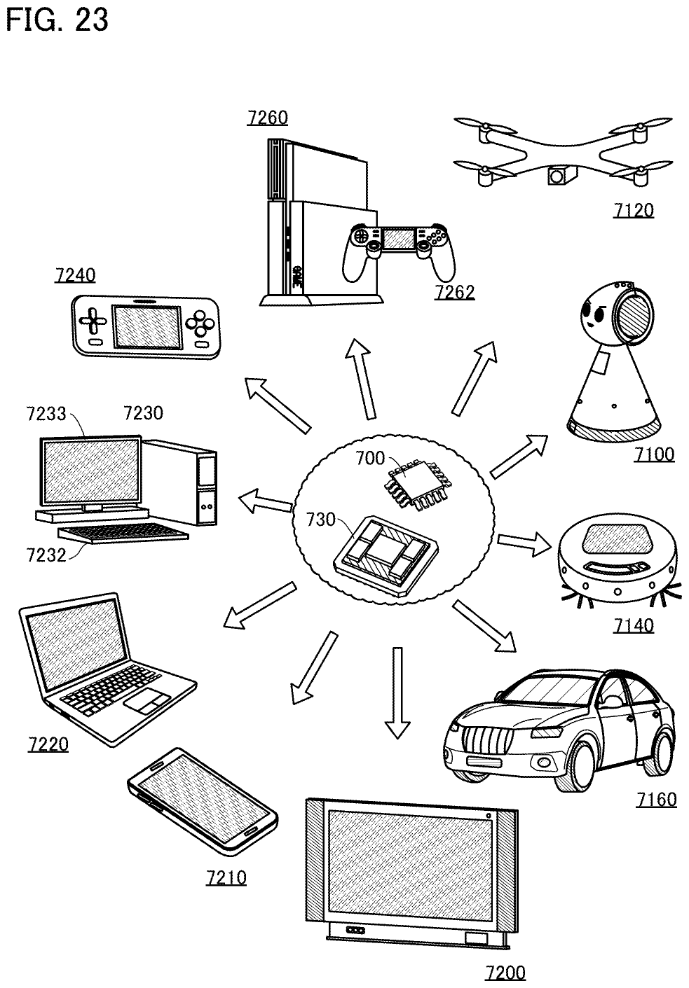

Next, examples of electronic devices including the electronic component are described with reference to FIG. 23.

A robot 7100 includes an illuminance sensor, a microphone, a camera, a speaker, a display, various kinds of sensors (an infrared ray sensor, an ultrasonic wave sensor, an acceleration sensor, a piezoelectric sensor, an optical sensor, a gyro sensor, and the like), a moving mechanism, and the like. The electronic component 730 includes a processor or the like and has a function of controlling these peripheral devices. For example, the electronic component 700 has a function of storing data obtained by the sensors.

The microphone has a function of detecting acoustic signals of a voice of a user, an environmental sound, and the like. In addition, the speaker has a function of outputting audio signals such as a voice and a warning beep. The robot 7100 can analyze an audio signal input via the microphone and can output a necessary audio signal from the speaker. The robot 7100 can communicate with the user with use of the microphone and the speaker.

The camera has a function of taking images of the surroundings of the robot 7100. In addition, the robot 7100 has a function of moving with use of the moving mechanism. The robot 7100 can take images of the surroundings with use of the camera and analyze the images to sense whether there is an obstacle in the way of the movement, for example.

A flying object 7120 includes propellers, a camera, a battery, and the like and has a function of flying autonomously. The electronic component 730 has a function of controlling these peripheral devices.

For example, image data taken by the camera is stored in the electronic component 700. The electronic component 730 can analyze the image data to sense whether there is an obstacle in the way of the movement, for example. Moreover, the electronic component 730 can estimate the remaining battery level from a change in the power storage capacity of the battery.

A cleaning robot 7140 includes a display provided on a top surface, a plurality of cameras provided on a side surface, a brush, an operation button, various kinds of sensors, and the like. Although not illustrated, the cleaning robot 7140 is provided with a tire, an inlet, and the like. The cleaning robot 7140 can run autonomously, detect dust, and vacuum the dust through the inlet provided on a bottom surface.

For example, the electronic component 730 can analyze images taken by the cameras to judge whether there is an obstacle such as a wall, furniture, or a step. In the case where an object that is likely to be caught in the brush, such as a wire, is detected by image analysis, the rotation of the brush can be stopped.

A motor vehicle 7160 includes an engine, tires, a brake, a steering gear, a camera, and the like. For example, the electronic component 730 performs control for optimizing the running state of the motor vehicle 7160 on the basis of navigation information, the speed, the state of the engine, the gearshift state, the use frequency of the brake, and other data. For example, image data taken by the camera is stored in the electronic component 700.

The electronic component 700 and/or the electronic component 730 can be incorporated in a TV device 7200 (a television receiver), a smartphone 7210, PCs (personal computers) 7220 and 7230, a game machine 7240, a game machine 7260, and the like.

For example, the electronic component 730 incorporated in the TV device 7200 can function as an image processing engine. The electronic component 730 performs, for example, image processing such as noise removal and resolution up-conversion.

The smartphone 7210 is an example of a portable information terminal. The smartphone 7210 includes a microphone, a camera, a speaker, various kinds of sensors, and a display portion. These peripheral devices are controlled by the electronic component 730.

The PC 7220 and the PC 7230 are respectively examples of a laptop PC and a desktop PC. To the PC 7230, a keyboard 7232 and a monitor device 7233 can be connected with or without a wire. The game machine 7240 is an example of a portable game machine. The game machine 7260 is an example of a stationary game machine. To the game machine 7260, a controller 7262 is connected with or without a wire. The electronic component 700 and/or the electronic component 730 can also be incorporated in the controller 7262.

This embodiment can be implemented in an appropriate combination with the structures described in the other embodiments and the like.

### Supplementary Notes on the Description in this Specification and the Like

The description of the above embodiments and each structure in the embodiments are noted below.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there can be a case where one circuit is associated with a plurality of functions or a case where a plurality of circuits are associated with one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, the size, the layer thickness, or the region is not necessarily limited to the illustrated scale. Note that the drawings are schematically shown for clarity, and embodiments of the present invention are not limited to shapes, values, or the like shown in the drawings. For example, variation in signal, voltage, or current due to noise, variation in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the terms “electrode” and “wiring” do not functionally limit these components. For example, an “electrode” is used as part of a “wiring” in some cases, and vice versa. Furthermore, the terms “electrode” and “wiring” also include the case where a plurality of “electrodes” and a plurality of “wirings” are formed in an integrated manner, for example.

Furthermore, in this specification and the like, “voltage” and “potential” can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential applied to a wiring or the like is sometimes changed depending on the reference potential.

In this specification and the like, the terms “film” and “layer” can be interchanged with each other depending on the case or circumstances. For example, the term “conductive layer” can be changed into the term “conductive film” in some cases. Also, for example, the term “insulating film” can be changed into the term “insulating layer” in some cases.

In this specification and the like, a switch has a function of controlling whether current flows or not by being in a conduction state (an on state) or a non-conduction state (an off state). Alternatively, a switch has a function of selecting and changing a current path.

In this specification and the like, channel length refers to, for example, the distance between a source and a drain in a region where a semiconductor (or a portion where current flows in a semiconductor when a transistor is in an on state) and a gate overlap with each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap with each other or a region where a channel is formed.

In this specification and the like, the expression “A and B are connected” means the case where A and B are electrically connected to each other as well as the case where A and B are directly connected to each other. Here, the expression “A and B are electrically connected” means the case where electric signals can be transmitted and received between A and B when an object having any electric action exists between A and B.

### REFERENCE NUMERALS

10: semiconductor device, 20: peripheral circuit, 25: substrate, 30_B: circuit unit layer, 30: circuit unit, 40: element layer, 41: electrode, 42: electrode, 43: electrode, 44: through electrode, 50: substrate, 60: memory circuit

1. A semiconductor device comprising:
a first substrate;
a second substrate over the first substrate;
a first element layer over and in contact with the second substrate; and
a first through electrode in the second substrate and the first element layer,
wherein the first element layer comprises:
a first transistor in the first element layer;
a first electrode electrically connected to the first through electrode;
a second electrode; and
a third electrode on a surface of the first element layer,
wherein the third electrode is electrically connected to the first electrode via the second electrode,
wherein the first transistor comprises a semiconductor layer comprising a metal oxide in a channel formation region,
wherein the first through electrode is exposed on a surface of the second substrate,
wherein the first through electrode is electrically connected to the first electrode,
wherein the second substrate and the first element layer stack up in a direction perpendicular or substantially perpendicular to a surface of the first substrate, and
wherein the first transistor and the first through electrode overlap each other.

2. A semiconductor device comprising:
a first substrate;
a second substrate over the first substrate;
a first element layer in contact with the second substrate; and
a first through electrode in the second substrate and the first element layer,
wherein the first element layer comprises:
a first memory cell in the first element layer;
a first electrode electrically connected to the first through electrode;
a second electrode; and
a third electrode on a surface of the first element layer,
wherein the first electrode is electrically connected to the first through electrode,
wherein the third electrode is electrically connected to the first electrode via the second electrode,
wherein the first memory cell comprises a first transistor and a capacitor,
wherein the first transistor comprises a semiconductor layer comprising a metal oxide in a channel formation region,
wherein the first through electrode is exposed on a surface of the second substrate,
wherein the second substrate and the first element layer stack up in a direction perpendicular or substantially perpendicular to a surface of the first substrate, and
wherein the first through electrode and each of the first transistor and the capacitor overlap each other.

3. A semiconductor device comprising:
a first substrate;
a second substrate over the first substrate;
a first element layer over and in contact with the second substrate; and
a first through electrode in the second substrate and the first element layer,
wherein the first element layer comprises:
a first memory cell in the first element layer;
a first electrode electrically connected to the first through electrode;
a second electrode; and
a third electrode on a surface of the first element layer,
wherein the third electrode is electrically connected to the first electrode via the second electrode,
wherein the first memory cell comprises a first transistor and a magnetic tunnel junction element,
wherein the first transistor comprises a semiconductor layer comprising a metal oxide in a channel formation region,
wherein the first through electrode is exposed on a surface of the second substrate,
wherein the second substrate and the first element layer stack up in a direction perpendicular or substantially perpendicular to a surface of the first substrate, and
wherein the first through electrode and each of the first transistor and the magnetic tunnel junction element overlap each other.

4. The semiconductor device according to claim 3, wherein the magnetic tunnel junction element comprises a stacked-layer structure of an unfixed layer, an insulating layer and a fixed layer.

5. A semiconductor device comprising:
a first substrate;
a second substrate over the first substrate;
a first element layer over and in contact with the second substrate; and
a first through electrode in the second substrate and the first element layer,
wherein the first element layer comprises:
a first plurality of memory cells;
a first circuit;
a first electrode electrically connected to the first through electrode;
a second electrode; and
a third electrode on a surface of the first element layer,
wherein the third electrode is electrically connected to the first electrode via the second electrode,
wherein the first plurality of memory cells and the first circuit each comprise a transistor comprising a metal oxide in a channel formation region,
wherein the first through electrode is exposed on a surface of the second substrate,
wherein the second substrate and the first element layer stack up in a direction perpendicular or substantially perpendicular to a surface of the first substrate, and
wherein the first through electrode and the transistor of the first circuit overlap each other.

6. The semiconductor device according to claim 5,
wherein one of the first plurality of memory cells is electrically connected to one of a plurality of bit lines, and
wherein the first circuit is configured to select any one of the plurality of bit lines and amplify and output a potential of the selected bit line.

7. The semiconductor device according to claim 5,
wherein each of the first plurality of memory cells is electrically connected to a word line, and
wherein the first circuit is configured to amplify a signal supplied to the word line.

8. The semiconductor device according to claim 1, further comprising a first peripheral circuit over the first substrate to drive the first transistor.

9. The semiconductor device according to claim 1, wherein the second electrode is provided in a layer where an electrode connected to the first transistor is provided.

10. The semiconductor device according to claim 1, wherein the second substrate is a silicon substrate.

11. The semiconductor device according to claim 1, wherein the metal oxide comprises In, Ga and Zn.

12. The semiconductor device according to claim 3, further comprising a first peripheral circuit over the first substrate to drive the first transistor.

13. The semiconductor device according to claim 2, wherein the second substrate is a silicon substrate.

14. The semiconductor device according to claim 2, wherein the metal oxide comprises In, Ga and Zn.

15. The semiconductor device according to claim 3, wherein the second substrate is a silicon substrate.

16. The semiconductor device according to claim 3, wherein the metal oxide comprises In, Ga and Zn.

17. The semiconductor device according to claim 5, wherein the second substrate is a silicon substrate.

18. The semiconductor device according to claim 5, wherein the metal oxide comprises In, Ga and Zn.
